(19) United States
(12) Patent Application Publication
(10) Pub. No.: US 2022/0360039 A1
(43) Pub. Date: Nov. 10, 2022

(54) LASER PACKAGE AND SYSTEM WITH LASER PACKAGES

(71) Applicants: OSRAM Opto Semiconductors GmbH, Regensburg (DE); Lumus Ltd., Ness Ziona (IL)

(72) Inventors: Ann Russell, SAN JOSE, CA (US); Yochay Danziger, Kfar Vradim (IL); Jörg Erich Sorg, Regensburg (DE); Hubert Halbritter, Dietfurt (DE); Alan Lenef, BELMONT, MA (US)

(21) Appl. No.: 17/764,912

(22) PCT Filed: Sep. 30, 2020
(86) PCT No.: PCT/EP2020/077314

§ 371 Date: Mar. 29, 2022

Related U.S. Application Data
(60) Provisional application No. 62/907,799, filed on Sep. 30, 2019.
(60) Provisional application No. 62/927,372, filed on Oct. 29, 2019.
(60) Provisional application No. 62/930,762, filed on Nov. 5, 2019.
(60) Provisional application No. 62/943,860, filed on Dec. 5, 2019.
(60) Provisional application No. 62/969,622, filed on Feb. 3, 2020.
(60) Provisional application No. 62/982,151, filed on Feb. 27, 2020.
(60) Provisional application No. 63/038,058, filed on Jun. 11, 2020.

(51) Int. Cl. H01S 5/02255; H01S 5/023; H01S 5/40; H01S 5/02335; H01S 5/0234; H01S 5/02257

(52) U.S. Cl. CPC H01S 5/02255; H01S 5/023; H01S 5/4056; H01S 5/02335; H01S 5/0234; H01S 5/02257; H01S 5/02415

(57) ABSTRACT

A laser package is described, the laser package comprising a plurality of laser diodes separately attached to at least one sub-mount having respective connecting pads, wherein, during operation, each of the laser diodes emits light having a fast axis and a slow axis defining a fast axis plane and a slow axis plane, wherein the fast axis planes of all laser diodes are parallel to each other and the distance between the fast axis planes of at least two laser diodes is smaller than the lateral distance between these laser diodes. Furthermore, a system with at least two laser packages is described.

### CROSS-REFERENCE TO RELATED APPLICATIONS

This patent application is a national stage entry from International Application No. PCT/EP2020/077314, filed on Sep. 30, 2020, published as International Publication No. WO 2021/063994 A1 on Apr. 8, 2021, and claims priority to U.S. Provisional Patent Application No. 62/907,799, filed Sep. 30, 2019, No. 62/982,151, filed Feb. 27, 2020, No. 63/038,058, filed Jun. 11, 2020, No. 62/927,372, filed Oct. 29, 2019, No. 62/930,762, filed Nov. 5, 2019, No. 62/943,860, filed Dec. 5, 2019, and No. 62/969,622, filed Aug. 14, 2019, the entire contents of all of which are incorporated by reference herein.

### FIELD OF THE INVENTION

This disclosure relates to laser packages and systems with laser packages, and, according to preferred embodiments, particularly to systems and methods for an efficient arrangement of chip on sub-mount assemblies (COSAs) for laser packages.

### BACKGROUND OF THE INVENTION

Laser diodes emit light along two different perpendicular axes, a fast axis and a slow axis. The emitted laser light diverges slowly, i.e., with a narrower beam divergence, along the slow axis and diverges quickly, i.e., with a wider beam divergence, along the fast axis. For example, if laser diodes of a row of lasers emit light in the same direction along their fast axis, there would be significant beam overlap. This may be beneficial in certain applications, such as virtual reality (VR) or augmented reality (AR) displays.

Laser packages may be constructed using COSAs, in which one or more laser diodes are placed on a sub-mount, and the package includes a number of sub-mounts forming an array. Traditional assembly techniques place the sub-mounts flat on a base such that each of the lasers emits light out of the package along its respective slow axis. In addition, the sub-mounts each take up a significant amount of surface area on the base so that there is a density limit regarding the number of laser diodes that can be placed in a package.

An object of at least certain embodiments is to specify ways, preferably more efficient ways, to arrange COSAs in a laser package. Another object of at least certain embodiments is to specify a system comprising at least two laser packages.

### SUMMARY OF THE INVENTION

According to at least one embodiment, a laser package comprises at least one laser diode. Preferably, the laser package comprises a plurality of laser diodes, wherein the laser diodes are separately attached to at least one sub-mount. Correspondingly, the laser package can comprises at least one sub-mount, wherein at least one or a plurality of laser diodes is/are attached to the sub-mount. Furthermore, the at least one sub-mount can include one or more conductors, for example formed by connecting pads. Moreover, the laser package can comprise a plurality of such sub-mounts, wherein one or more laser diodes is/are attached to each of the sub-mounts, respectively.

According to a further embodiment, the laser diodes emit light as a light beam during operation, the light having a fast axis defining a fast axis plane and a slow axis defining a slow axis plane. This can mean in particular that the fast axis plane of a laser diode can be the plane defined by the fast axis and the emission direction of the emitted light beam, while the slow axis plane can be the plane defined by the slow axis and the emission direction of the emitted light beam. Preferably, all fast axis planes of the laser diodes are parallel. Furthermore, the distance between the fast axis planes of at least two laser diodes can be smaller than the lateral distance between these laser diodes. Preferably, the distance between the fast axis planes can be measured in a direction perpendicular to the fast axis planes, while the lateral distance can be measured in a direction parallel to the fast axis planes, which can be, preferably, a direction perpendicular to the slow axis planes.

According to a further embodiment, the laser package includes a base and a plurality of sub-mounts. Each sub-mount preferably includes one or more laser diodes and respective connecting pads, wherein, during operation of the laser package, each of the one or more laser diodes emits light having a fast axis and a slow axis. Each sub-mount has a length, a width, and a height, the length and height defining a first surface.

According to preferred embodiments, each sub-mount may be attached to the base such that the first surface is parallel to the base. This may allow light emitted by each laser diode to exit the laser package along its fast axis, which leads to greater beam overlap. In addition, there may be a higher density of lasers per unit area of the base.

According to at least one further embodiment, a system comprises at least two laser packages.

### BRIEF DESCRIPTION OF THE DRAWINGS

Further features, advantages and expediencies of the laser package will become apparent from the following description of exemplary embodiments and features in conjunction with the figures. The embodiments shown in the figures and, in particular, the respective described features are not limited to the respective combinations of features shown in the figures. Rather, the shown embodiments as well as single features can be combined with one another, even if not all combinations are explicitly described.

FIGS. 1A and 1B are block diagrams illustrating a prior art laser package.

FIGS. 2A and 2B are block diagrams illustrating a laterally-oriented laser package in accordance with various embodiments.

FIGS. 3A and 3B are block diagrams illustrating a laterally-oriented laser package in accordance with various further embodiments.

FIG. 4 is a block diagram illustrating a laterally-oriented laser package in accordance with various further embodiments.

FIGS. 5A to 5D are block diagrams illustrating laterally-oriented laser packages without a prism in accordance with various further embodiments.

FIG. 6 shows a block diagram and various spot diagrams illustrating laterally-oriented laser packages sharing a reflecting mirror in accordance with various further embodiments.

FIG. 7 shows a block diagram and a spot diagram illustrating a prior art laser package sharing a reflecting mirror.

FIG. 8 shows block diagrams and spot diagrams illustrating laser packages emitting polarized light in accordance with various further embodiments.

FIG. 9 is a block diagram illustrating a flatly-oriented laser package emitting polarized light in accordance with various further embodiments.

FIG. 10 is a block diagram illustrating a laterally-oriented laser package emitting polarized light in accordance with various further embodiments.

FIG. 11 is a block diagram illustrating a flatly-oriented laser package emitting polarized light in accordance with various further embodiments.

FIG. 12 is a block diagram illustrating a laterally-oriented laser package emitting polarized light in accordance with various further embodiments.

FIG. 13 is a block diagram illustrating a flatly-oriented laser package emitting polarized light with the use of reflectors and lenses in accordance with various further embodiments.

FIG. 14 is a block diagram illustrating a laterally-oriented laser package emitting polarized light with the use of reflectors and lenses in accordance with various further embodiments.

FIGS. 15A and 15B are block diagrams demonstrating methods of astigmatism correction to the slow and fast axis of the beam diverging from a laterally-oriented laser package in accordance with various further embodiments.

FIGS. 16A and 16B are block diagrams illustrating flatly-oriented laser packages emitting light into a waveguide in accordance with various further embodiments.

FIGS. 17A and 17B are block diagrams illustrating laterally-oriented laser packages emitting light into a waveguide and a system with laser packages in accordance with various further embodiments.

FIG. 17C is a block diagram illustrating a system with a combination of a flatly-oriented and laterally-oriented laser package emitting light into waveguides in accordance with various further embodiments.

FIGS. 18A and 18B are block diagrams illustrating laser packages emitting light into a waveguide in accordance with various further embodiments.

FIGS. 19A to 19D are block diagrams illustrating systems with laser packages separated by individual packaging in accordance with various further embodiments.

FIG. 20 is a block diagram illustrating a laser package in combination with a photodiode in accordance with various further embodiments.

FIG. 21 is a block diagram illustrating a laser package with modified heat conductivities in accordance with various further embodiments.

FIG. 22 show block diagrams illustrating a laser package with heat conductivity modifications in accordance with various further embodiments.

FIG. 23 is a block diagram illustrating a laser package with heat conductivity modifications and a thermal sensor in accordance with various further embodiments.

FIG. 24 is a schematic illustration of a laser for a laser package with metallized pads on a substrate in accordance with various further embodiments.

FIG. 25 shows block diagrams illustrating sub-mounts with embedded conducting lines in accordance with various further embodiments.

FIG. 26 shows block diagrams illustrating sub-mounts with embedded conducting lines in accordance with various further embodiments.

FIG. 27 shows block diagrams illustrating PCBs (printed circuit boards) mounted to sub-mounts with embedded conducting lines in accordance with various further embodiments.

FIG. 28 is a block diagram illustrating a laser package with a micro-refrigerator in accordance with various further embodiments.

FIG. 29 is a block diagram illustrating a laterally-oriented laser package sharing a reflecting mirror and measured by an imaging inspection device in accordance with various further embodiments.

FIGS. 30A and 30B are block diagrams illustrating the layout of upper and lower plates of a laser package in accordance with various further embodiments.

FIG. 31 is a block diagram illustrating a flatly-oriented laser package sharing a reflecting mirror with additional optical elements in accordance with various further embodiments.

FIG. 32 is a block diagram illustrating a laterally-oriented laser package sharing a reflecting mirror with additional optical elements in accordance with various further embodiments.

FIG. 33 is a block diagram illustrating a flatly-oriented laser package sharing a reflecting mirror with additional optical elements in accordance with various further embodiments.

FIG. 34 is a block diagram illustrating a laterally-oriented laser package sharing a reflecting mirror with additional optical elements in accordance with various further embodiments.

### DETAILED DESCRIPTION

These and other features of the present embodiments will be understood better by reading the following detailed description, taken together with the figures herein described. The accompanying drawings are not intended to be drawn to scale. For purposes of clarity, not every component may be labeled in every drawing.

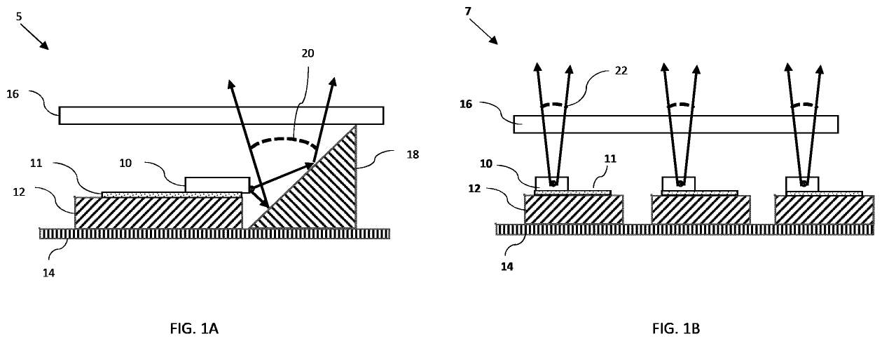

FIGS. 1A and 1B are block diagrams illustrating a prior art laser package. FIG. 1A is a side view 5 of the prior art laser package while FIG. 1B is a front view 7 of the same laser package showing multiple lasers. Each of the lasers of the laser package is formed by a laser assembly and includes a laser diode 10 on top of a connecting pad 11, which is placed on a sub-mount 12. The sub-mount 12 of each laser is attached to a base 14. The sub-mounts 12 may be rectangular in shape, with a height that is smaller than either the length or the width, respectively. Each of the sub-mounts 12 is placed on the base 14 such that the wider area rectangular face, defined by the length and width, is attached to and parallel to the base 14. Light emitted by the laser diodes 10 strikes a prism 18, which reflects the light through a window 16 and out of the package.

Each laser diode 10 emits light having a fast axis and a slow axis, which are perpendicular to each other. Accordingly, the emitted light has a fast axis plane that is the plane defined by the fast axis and the emission direction of the emitted light, while the slow axis plane is the plane defined by the slow axis and the emission direction of the emitted light. Side view 5 corresponds to a sectional view with a sectional plane parallel to the fast axis plane and thus provides a view of the beam divergence 20 along the fast axis while front view 7 corresponds to a sectional view with a sectional plane parallel to the slow axis plane and thus provides a view of the beam divergence 22 along the slow axis. As can be seen from the front view 7, the beams of each laser diode are relatively narrow and do not overlap. In addition, since the sub-mount 12 of each laser assembly is placed on the base 14 along the side with the greatest surface area, each sub-mount 12 takes up a considerable amount of space on the base 14. This limits the number of lasers that can be placed on the base 14 per unit area.

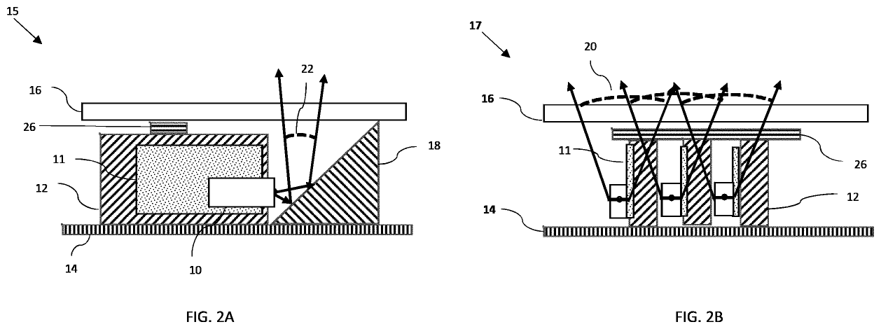

FIGS. 2A and 2B are block diagrams illustrating a laterally-oriented laser package in accordance with various embodiments. FIG. 2A is a side view 15 of the laser package while FIG. 2B is a front view 17 of the same laser package showing multiple lasers. Each laser of the laser package is formed as a laser assembly and includes a laser diode 10 on top of a connecting pad 11, which is placed on a sub-mount 12. Each sub-mount 12 is attached to a base 14. Consequently, the laser assemblies are placed adjacent to each other, so that paralleled light beams can be emitted during operation.

The sub-mounts 12 may be rectangular in shape, with a height that is smaller than either the length or the width or, preferably, both. However, unlike the prior art laser package shown in FIGS. 1A and 1B, each sub-mount 12 is placed on the base 14 such that a smaller area rectangular face, defined by the length and height, is attached to and parallel to the base 14. In other words, in FIGS. 2A and 2B the sub-mounts 12 are placed perpendicularly with respect to what is shown in FIGS. 1A and 1B. Light emitted by the laser diodes 10 strikes prism 18, which reflects the light through a window 16 and out of the package. There may also be a conducting bridge 26 placed across the sub-mounts 12 to improve heat dissipation and mechanical stability. The sub-mounts 12 may also be approximately the same width or length of the laser diodes 10, and the laser diodes 10 may be placed in any position on the respective sub-mount 12 as long as the emerging light beam has a clear path.

Each laser diode 10 emits light having a fast axis and a slow axis. Side view 15 corresponds to a sectional view with a sectional plane parallel to the slow axis plane and thus provides a view of the beam divergence 22 along the slow axis while front view 17 corresponds to a sectional view with a sectional plane parallel to the fast axis plane and thus provides a view of the beam divergence 20 along the fast axis, which is the reverse of what is shown in FIGS. 1A and 1B since the sub-mounts 12 have been rotated perpendicularly. Consequently, all fast axis planes of the laser diodes 10 are parallel. Furthermore, the distance between the fast axis planes of at least two laser diodes 10 are smaller than the lateral distance between these laser diodes, wherein the distance between the fast axis planes is measured in a direction perpendicular to the fast axis planes, while the lateral distance is measured in a direction parallel to the fast axis planes, which can be, preferably, a direction perpendicular to the slow axis planes. Particularly preferably, as shown in FIGS. 2A and 2B, said distance relation applies to all pairs of laterally directly adjacent laser diodes 10. In particular, the distance between the fast axis planes of at least two laser diodes 10 or even the respective distance between the fast axis planes between all pairs of laterally directly adjacent laser diodes 10 can be 0 or a least substantially 0. The described distance relation can also apply to the following embodiments, even if it is not mentioned explicitly.

As can be seen from the front view 17, the beams of each laser diode 10 are relatively wide and overlap. In addition, since the sub-mounts 12 of each laser assembly are placed on the base 14 along the side with a smaller surface area, each sub-mount 12 takes up a less space on the base 14 compared to what is shown in FIGS. 1A and 1B. This also allows a greater number of lasers to be placed on the base 14 per unit area. The combination of greater beam overlap and more lasers per unit area is beneficial for certain applications, such as VR or AR displays. For example, in an AR laser matrix, the scan time is inversely proportional to the number of lasers in the matrix. Thus having more lasers in the same size laser matrix reduces the scan time. Another advantage is increasing the field of view (FOV) of the AR system due to having greater beam divergence and beam overlap. For example, a FOV of approximately 50° may be achieved.

The laser package illustrated in FIGS. 2A and 2B may be fabricated by bonding a laser diode, which may be also denoted as laser die in the following, on an aluminum nitride or other ceramic sub-mount, which may comprise one or more connecting pads. For instance, the laser diode may by mounted on a connecting pad. One or more wire bonds may be attached to the top of the laser diode and to one or more connecting pads, for instance including the grounded portion of the sub-mount, forming a COSA. The COSA is rotated by 90° and then bonded on its side to the base. This allows adjacent COSAs to be placed very close to each other, for example with spacing less than 400 micrometers. In RBG applications, adjacent COSAs may have red, green, and blue lasers that share a prism. This arrangement aligns the fast axis of each laser laterally.

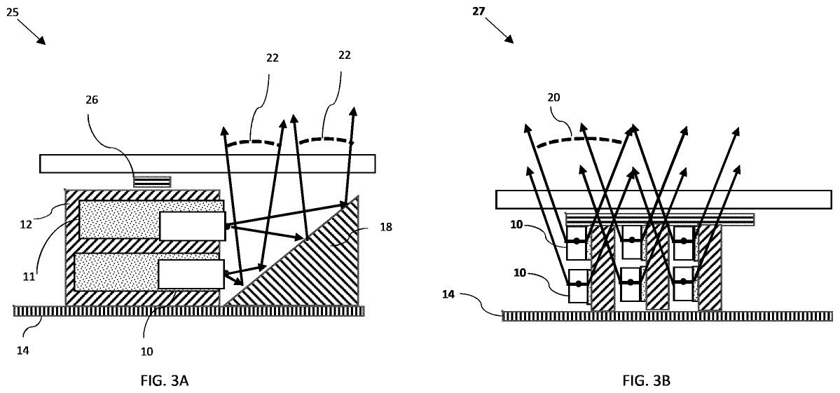

FIGS. 3A and 3B are block diagrams illustrating a laterally-oriented laser package in accordance with various further embodiments. FIG. 3A is a side view 25 of the laser package while FIG. 3B is a front view 27 of the same laser package showing multiple lasers. The laser package is similar to that shown in FIGS. 2A and 2B except that the sub-mounts 12 each support two laser diodes 10, each with their respective connecting pad 11, so that each laser assembly comprises two laser diodes 10, respectively. In the embodiments shown, the connecting pads 11 are placed under the laser diodes 10 rather than next to them so that the laser diodes on each sub-mount 12 may be placed closer together.

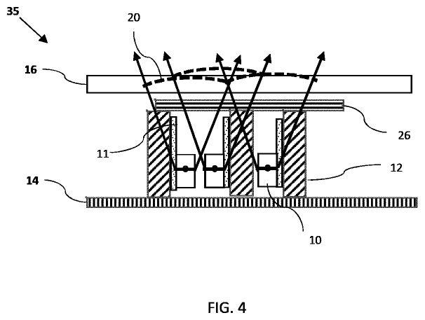

FIG. 4 is a block diagram illustrating a front view 35 of a laterally-oriented laser package in accordance with various further embodiments. The laser package is similar to that shown in FIG. 2B except that one sub-mount 12, in the shown embodiment by way of example the one on the left in FIG. 4, is oriented in the opposite direction in comparison to the other sub-mounts 12. This means that the spacing between the oppositely oriented laser, i.e., the laser diode with the sub-mount 12 oriented in the opposite direction comparison to the other sub-mounts 12, and the adjacent laser is shorter, which leads to greater beam overlap. In addition, if the oppositely oriented laser is located on one edge of the laser array, the distance between the lasers on either edge is shorter than the layout shown in FIGS. 2A and 2B, which leads to a larger overlap of color fields and therefore a greater projected “white” field. The unequal distance between lasers may be compensated electronically.

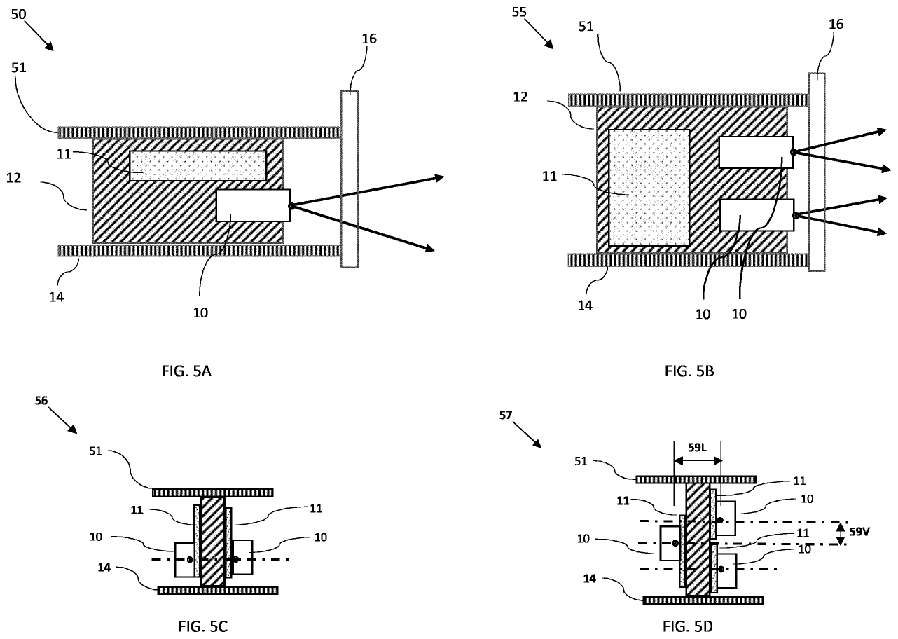

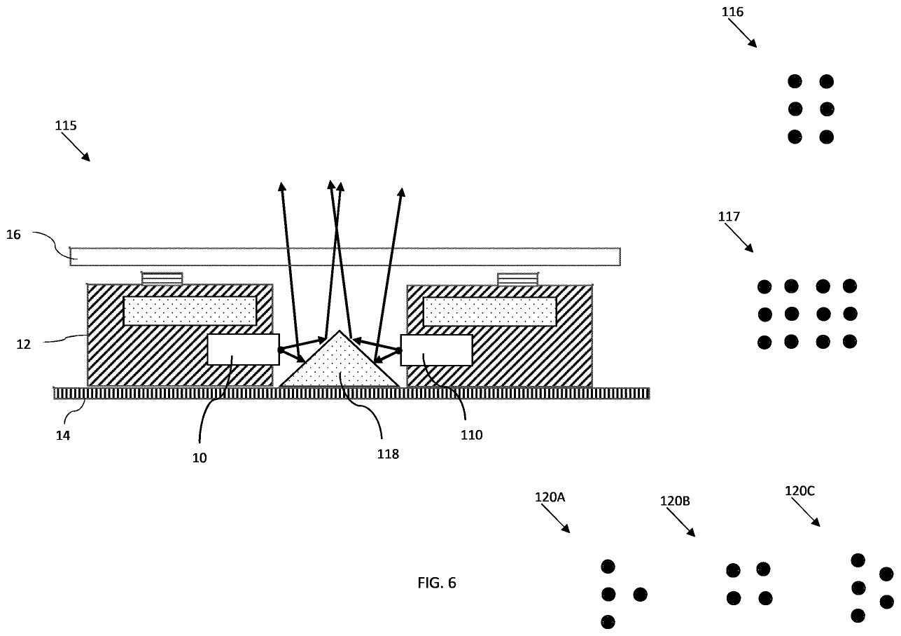

FIGS. 5A to 5D are block diagrams illustrating a laterally-oriented laser package without a prism in accordance with various further embodiments. FIG. 5A is a side view 50 of a laser package that includes one or preferably several lasers, each with a laser diode 10, one or more connecting pads 11 and a sub-mount 12, as well as base 14 and window 16. As opposed to the configuration of the embodiment shown in FIG. 2A, there is no prism and the window 16 is placed directly in front of laser diode 10. This is possible because the slow axis beam divergence from laser diode 10 may propagate further without encountering the base 14. A top cover 51 is also placed on the opposite side of the base 14 in the laser package. The top cover 51 may be metallic or ceramic to enable more efficient heat removal from the top side of the laser package.

FIG. 5B is a side view 55 of a laser package that includes one or preferably several lasers, each with two or more laser diodes 10, one or more connecting pad 11s and a sub-mount 12, as well as base 14, top cover 51 and window 16. Similar to the embodiment shown in FIG. 5A, the two laser diodes 10 emit light directly out of the window 16 without the use of a prism. The two laser diodes 10 may share the same connecting pad 11, or may each have individual connecting pads 11. Again, the top cover 51 may be metallic to enable more efficient heat removal from the top side of the laser package.

FIG. 5C is a front view 56 of a laser package with at least one laser assembly having two lasers diodes 10 separately attached on opposing sides of the same sub-mount, so that at least one laser diode is arranged on each of both sides of the sub-mount. The dot-dashed line represents the fast axis diverging plane of both laser diodes 10. The two laser diodes 10 have parallel and overlapping fast axis planes.

FIG. 5D is a front view 57 of a laser package having at least one laser assembly with more laser diodes 10 attached to the same sub-mount, wherein the laser diodes 10 have parallel fast axis planes. Between each of the pairs of laser diodes 10 that are closest arranged to each other along the vertical direction the distance 59V between the fast axis planes is smaller than the lateral distance 59L, i.e., the distance parallel to the fast axis planes, between these laser diodes 10. Therefore, for most optical purposes, for instance such as aperture size setting, the planes are considered overlapping. The laser packages according to FIGS. 5C and 5D can be implemented to the laser packages shown in FIGS. 5A and 5B as well as to all other configurations described herein.

FIG. 6 shows a block diagram illustrating a laterally-oriented laser package sharing a reflecting mirror in accordance with various further embodiments. Side view 115 shows one of several pairs of two oppositely facing laser assemblies placed opposite to each other, one comprising one or more laser diode 10 and the other comprising one or more laser diode 110, so that only one laser diode 10 of one of the laser assemblies on the left side and only one laser diode 110 of one of the laser assemblies on the right side can be seen in the side view 115, and each of the laser diodes 10, 110 emitting light onto a reflecting mirror 118 placed in-between, e.g., in the middle, so that paralleled light beams are emitted during operation. This configuration allows for closely packed illumination spots. The reflecting mirror 118 may have two sides with reflecting planes such that light emitted by each laser assembly can be reflected at right angles and can exit window 16. For instance, the reflecting mirror 118 may have a right angle between the reflecting planes. The reflecting mirror 118 can also be a prism as described above. The laser diodes 10 and opposing laser diodes 110 may be placed at the same distance from the reflecting mirror 118 so that the lasers are focused onto the image plane simultaneously. Each laser package may include cascaded lasers, each emitting a different color. For example, schematic spot diagram 116 shows three laser spots, for instance RBG colors, from laser diodes 10, which may be arranged in a cascaded array as shown in FIG. 2B, and three laser spots, for instance RBG colors, from opposing laser diodes 110. Schematic spot diagram 117 shows the same reflecting mirror implementation, but with the double laser diode configuration of the embodiment shown in FIGS. 3A and 3B. This results in four sets of RBG spots, two sets coming from each side of laser assemblies. The reflecting mirror 118 may have to be larger to accommodate multiple laser diodes on each assembly and side with respect to the reflecting mirror 118. Schematic spot diagrams 120A, 120B, and 120C show embodiments of non-symmetric spot distributions, in which for each side of the prism 118 there are different numbers of lasers or different color distributions. For example, in diagram 120A, there is one laser on one side and three on the other side, in diagram 120B there are two lasers on each side but with different colors, e.g., R-G and B-R, and in diagram 120C there are two lasers on one side and three lasers on the other side, e.g., R-G-B and R-G.

The color arrangement of the lasers may be modified according to various considerations. For example, blue laser light is considered more harmful and therefore, when more blue lasers are used, the local intensity should be reduced. To account for this effect, the laser color arrangement in schematic spot diagram 116 may be:

B-R-B

G-B-G

Another consideration is the fact that a red laser diode is usually weaker in power while the blue one is the strongest, so that a low power laser color arrangement in schematic spot diagram 116 may be:

R-B-R

G-R-G

In another example, a low-cost modular arrangement may include the same color arrangement for both opposing laser blocks in side view 115, so the schematic spot diagram 116 may be:

R-G-B

B-G-R

In another example, when using the dual laser package shown in side view 55 of the embodiment of FIG. 5B, the two adjacent laser diodes may be the same. As a result, the laser color arrangement in schematic spot diagram 116 may be:

R-G-B

R-G-B

In another example, e.g., for LIDAR applications, when using the dual laser package shown in side view 55 of the embodiment of FIG. 5B, the two adjacent lasers may be all the same. As a result, the laser color arrangement in schematic spot diagram 116 may be:

B-B-B

B-B-B

In this case multiple spots can be provided for scanning the

LIDAR field simultaneously, thereby increasing the scanning throughput. Alternatively, LIDAR applications may also implement the following schematic spot diagram:

B-IR-IR

IR-IR-IR

In this case, the visible blue light can mark the IR scanning area, thereby making a LIDAR scan visible. The IR light emitter could be an 850 nm, 940 nm, or 905 nm IR laser, for example with application in LIDAR, driver monitoring, and exterior safety halos of autonomous vehicles.

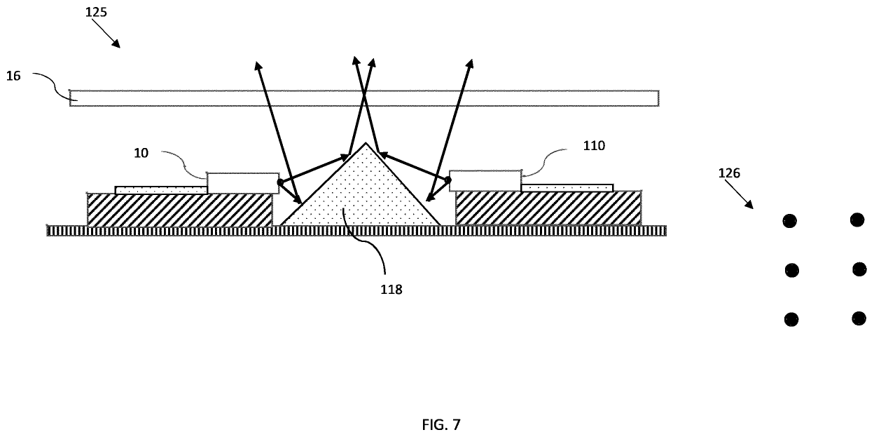

FIG. 7 is a block diagram illustrating a prior art laser package with a shared reflecting mirror. As opposed to the lateral orientation shown in the embodiments of FIG. 6, mounting the sub-mounts flat on the base, as shown in FIGS. 1A and 1B, requires a larger reflecting mirror 118 as shown in the side view 125 of FIG. 7. Consequently, the laser spots in the schematic spot diagram 126 are further apart compared to the schematic spot diagram 116 shown in FIG. 6.

As shown, it possible to use two lasers having different polarization for creating a scanning field, thereby generating a perception to the observer of uniform illumination originated by an unpolarized laser. In such prior art configurations, the difference in polarization between the two lasers is created by having the lasers differ slightly in wavelength and implementing a birefringent window on the overlapping beams.

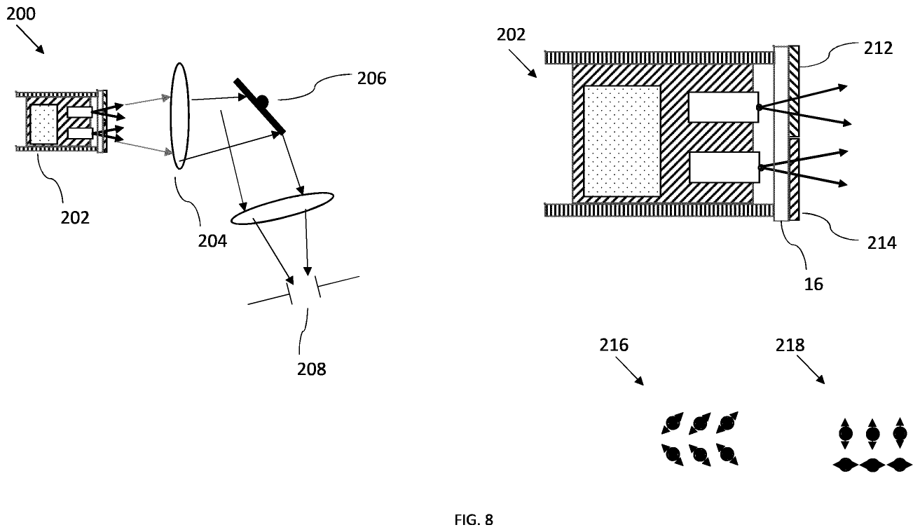

According to further embodiments it can be advantageous to use a wave-plate polarizer or other polarization means like a polarization conversion film such that s and p polarization of the emitted light are balanced. FIG. 8 is a block diagram illustrating laser packages emitting polarized light in accordance with various further embodiments. Top view 200 shows a laser package 202 projecting light that will enter into a waveguide (not shown). In many such configurations it is important to introduce unpolarized light into the waveguide. The light from the laser package 202 passes through optics 204, steered by a scanning mirror 206, and exits through exit pupil 208, e.g., the entrance pupil to the waveguide. This system only includes components that are polarization insensitive.

As opposed to the prior art configuration for creating polarization, the polarization of the lasers is performed at locations where the beams are separated as shown in FIG. 8. The laser package 202, as shown in detail on the right-hand side of FIG. 8, includes at least one laser with two laser diodes on a single sub-mount, similar to the configuration of the embodiment shown in FIG. 5B. In some embodiments, the laser diodes have the same wavelength. Three such laser packages may be placed perpendicularly side by side. Window 16 covers the laser package 202. A variable wave-plate is placed on top of the window, having two sections 212 and 214. The wave-plate sections 212, 214 are set to differentiate the output beam polarization originated from different laser diodes. The two sections 212, 214 have, for example, different orientations. For example, if the two sections 212, 214 have a retardation of λ/2 and have opposite angles of 22.5° relative to the lasers' fast axis, the polarization that results is shown in polarization spot diagram 216. Alternatively, for the case that wave-plate section 212 has no polarization activity and wave-plate section 214 has a polarization of λ/2 at 45°, the resulting polarization is shown in polarization spot diagram 218.

Alternatively, the wave-plate sections 212 and 214 may be λ/4-wave-plates at +45° and −45° relative to the laser's or laser diodes' polarizations, which results in positive and negative circular polarizations as output polarizations. Therefore, any alternate orthogonal polarization configurations may be produced, e.g., perpendicular polarizations defined as opposite vectors in the Poincare sphere. Alternatively, if more than two laser diodes are used for a color, then this color may have distributions of polarizations that average to a total of zero polarization.

In addition, laser diodes of the same color may be slightly wavelength shifted to suppress coherent undesired artifacts. Furthermore, depolarization and relative polarization rotation may be achieved using a combination of the methods described herein in addition to the use of wave-plates. For example, the laser diodes may be slightly wavelength shifted and a birefringent element may be introduced into the beam path.

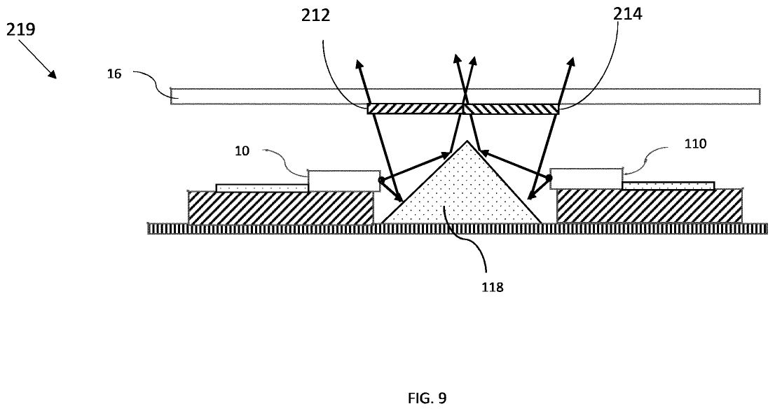

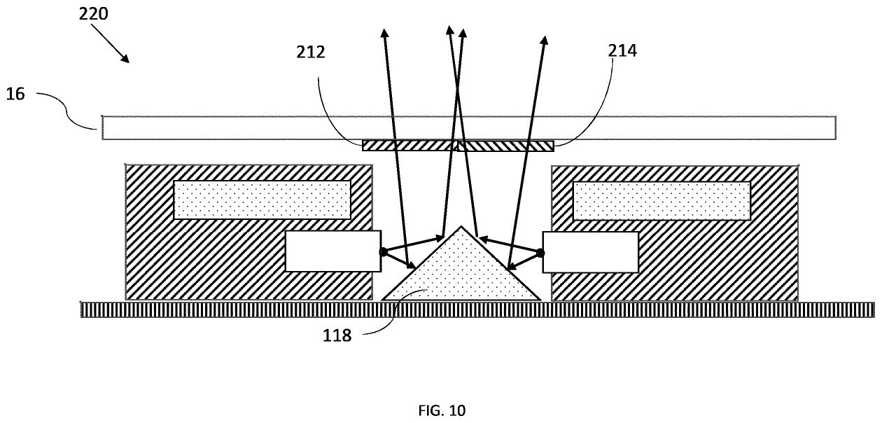

FIG. 9 is a block diagram illustrating a flatly-oriented laser package emitting polarized light in accordance with various further embodiments. Side view 219 shows two opposing laser diodes 10, 110 emitting light onto reflecting mirror 118. The lasers are placed flatly on a base, similar to the configuration shown in FIG. 7. The light reflected from mirror 118 passes through wave-plate sections 212, 214 before exiting window 16.

FIG. 10 is a block diagram illustrating a laterally-oriented laser package emitting polarized light in accordance with various further embodiments. Side view 220 shows two opposing lasers emitting light onto reflecting mirror 118. The lasers are placed laterally on a base, similar to the configuration of the embodiment shown in FIG. 6. The light reflected from mirror 118 passes through wave-plate sections 212, 214 before exiting window 16.

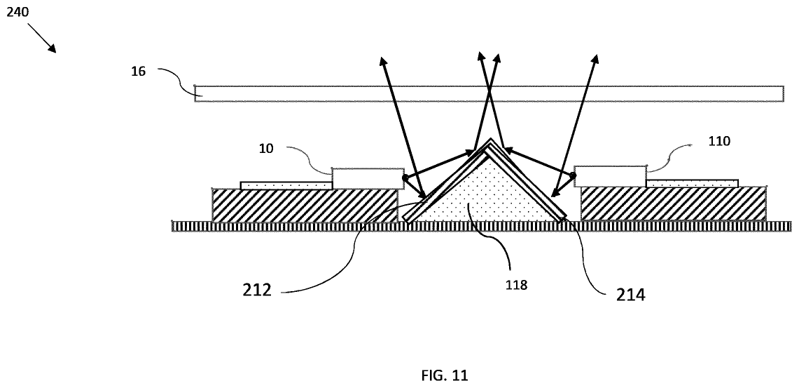

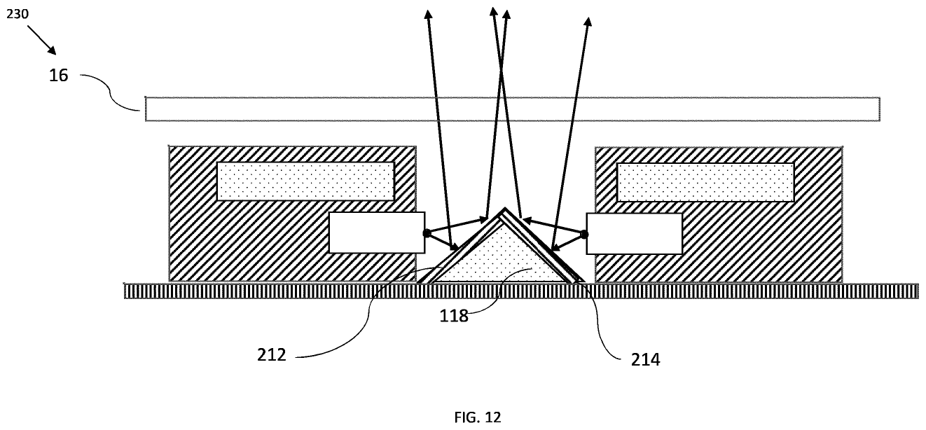

FIG. 11 is a block diagram illustrating a flatly-oriented laser package emitting polarized light in accordance with various further embodiments. Side view 240 shows two opposing lasers 10, 110 emitting light onto reflecting mirror 118. The lasers are placed flatly on a base, similar to the configuration of the embodiment shown in FIG. 7. Instead of placing wave-plate sections 212, 214 in front of a window 16 as shown in FIG. 9, the sections 212, 214 are placed on the faces of the reflecting mirror 118.

FIG. 12 is a block diagram illustrating a flatly-oriented laser package emitting polarized light in accordance with various further embodiments. Side view 230 shows two opposing lasers emitting light onto reflecting mirror 118. The lasers are placed laterally on a base, similar to the configuration of the embodiment shown in FIG. 6. Instead of placing wave-plate sections 212, 214 in front of window 16 as shown in FIG. 10, the sections 212, 214 are placed on the faces of the reflecting mirror 118.

In some embodiments, the wave-plate sections 212, 214 described in connection with FIGS. 9 to 12 may be a single section with spatially varying polarization properties. The variation may be continuous and may be where the beams from the lasers are overlapping.

The configurations shown in FIGS. 11 and 12 may also produce even polarization. The reflecting mirror 118 in FIGS. 11 and 12 may be coated by wave-plate sections 212, 214. The coatings forming the sections 212 and 214 would result in different polarizations of laser light leaving the package. In some embodiments, the coatings may be applied such that the light leaving the mirror 118 is an even distribution of s and p polarized light or light rotated by 90 degrees having been reflected off the mirror 118.

The difference in the slow and fast divergence of the laser beam may cause loss of power. To address this issue, optics may be integrated into the laser package or adjacent to it in order to generate a more symmetric beam.

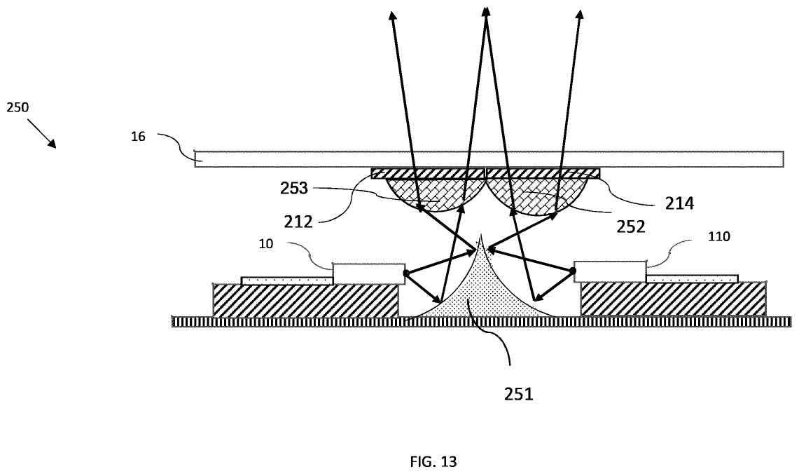

FIG. 13 is a block diagram illustrating a flatly-oriented laser package emitting polarized light with the use of reflectors and lenses in accordance with various further embodiments. Side view 250 shows two opposing lasers emitting light onto a concave curved reflector 251. The lasers are placed laterally on a base, similar to the configuration of the embodiment shown in FIG. 6. The concave curved reflector 251 decreases the divergence in the fast axis to match the slow axis. After reflecting off the concave curved reflector 251 and decreasing divergence rapidly, the laser light enters cylindrical lenses 252, 253 and passes through wave-plate sections 212 and 214 as described previously. Once passing through the exit window 16 the fast axis now matches the divergence of the slow axis. Now each side has approximately the same beam divergence and is equally weighted between s and p polarization.

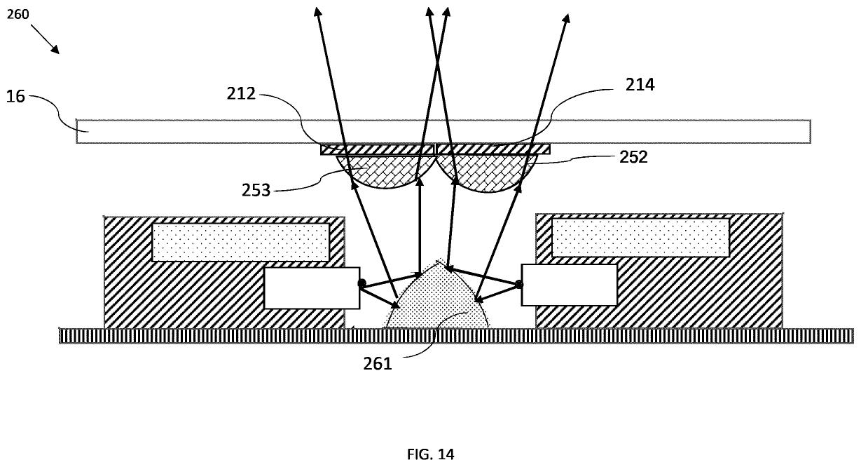

FIG. 14 is a block diagram illustrating a laterally-oriented laser package emitting polarized light with the use of reflectors and lenses in accordance with various further embodiments. Side view 260 shows two opposing lasers emitting light onto a convex curved reflector 261. The lasers are placed laterally on a base, similar to the configuration shown in FIG. 6. The convex curved reflector 261 that is centered between the lasers increases the divergence of the slow axis. The now more divergent beams enter cylindrical lenses 252, 253, respectively, to decrease the divergence once again so that the divergence of the slow axis matches the fast axis. The beams then pass through wave-plate sections 212 and 214 and the window 16. Now each side of the laser package has approximately the same beam divergence and with orthogonal polarizations.

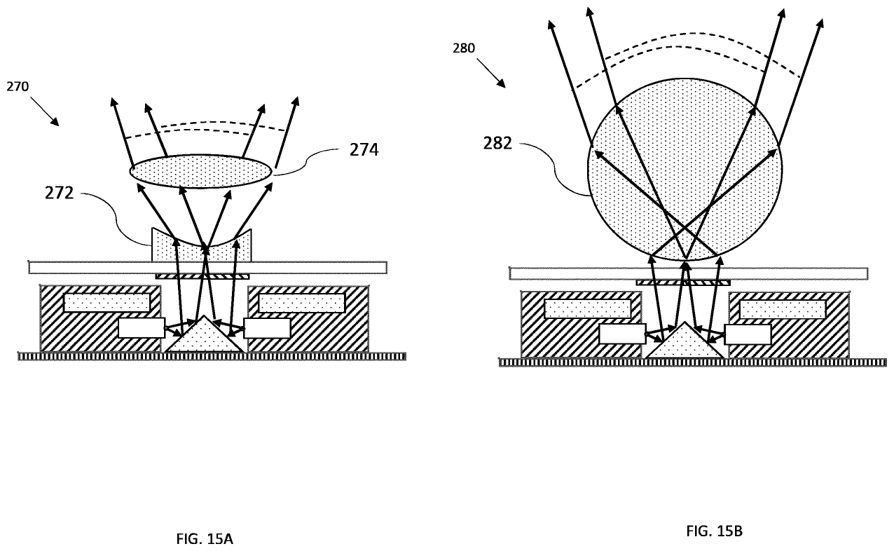

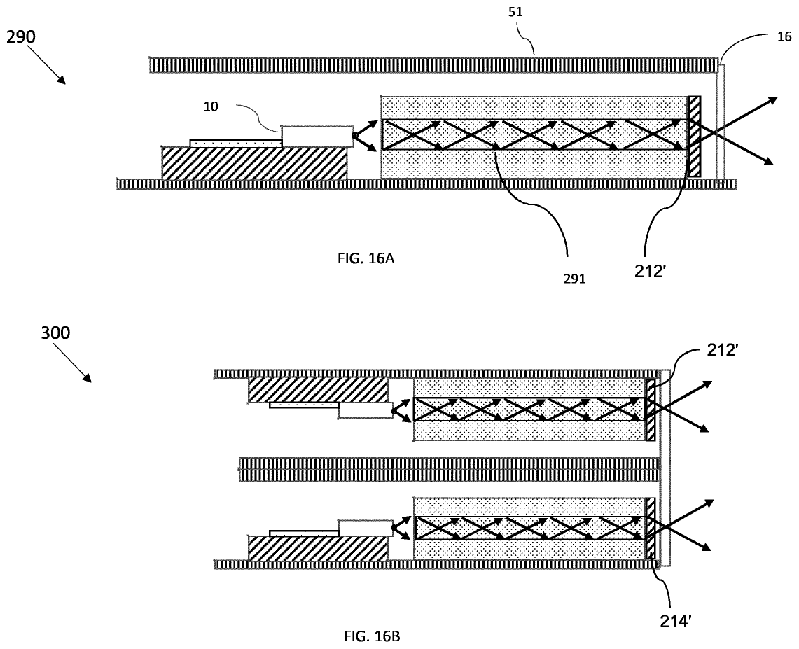

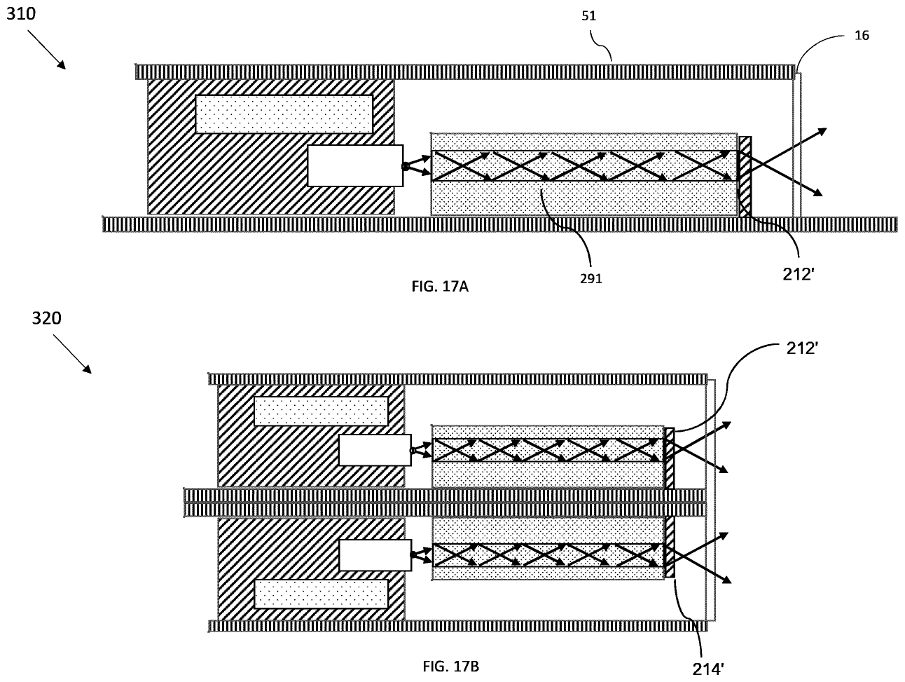

FIGS. 15A and 15B are block diagrams demonstrating methods of astigmatism correction to the slow and fast axis of the beam diverging from a laterally-oriented laser package in accordance with various further embodiments. Side view 270 illustrates the optics for slow axis expansion adjacent and outside of window 16. Side view 270 in FIG. 15A shows two opposing lasers emitting light onto a reflecting mirror. The lasers are placed laterally on a base, similar to the configuration of the embodiment shown in FIG. 6. Lens 272 is placed on top of the window and is used to increase the divergence of the slow axis diverging beam. Lens 274 is placed at some distance from lens 272 and reduces the divergence to be equivalent to that of the fast axis. In this configuration the lenses 272 and 274 may simultaneously manipulate the beams from all the lasers in the package in a Galilean type reverse telescope manner. Consequently, the lateral distance between laser sources will appear to be closer, as preferred for astigmatism correction in AR or VR applications.

FIG. 15B illustrates an alternate method for achieving the same results. In this case, side view 280 shows two opposing lasers emitting light onto a reflecting mirror. The lasers are placed laterally on a base, similar to the configuration shown in FIG. 6. Light exiting the lasers enters an optical rod 282. This rod performs the same function as the lenses 272, 274 in FIG. 15A, but in a Keplerian type reverse telescope manner where the beam first focuses and afterward diverges. The optical rod 282 may be a uniform glass or a graded index lens.

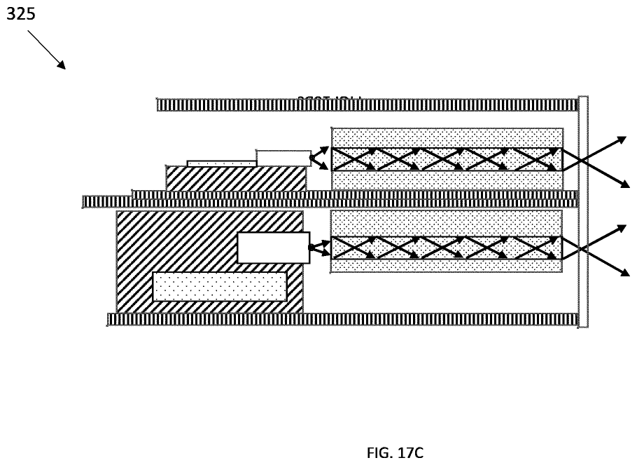

FIGS. 16A and 16B are block diagrams illustrating flatly-oriented laser packages emitting light into a waveguide 291 in accordance with various further embodiments. In this case side view 290 in FIG. 16A shows a flat mounted laser diode 10 injecting light into a first end of an adjacent waveguide 291, wherein the waveguide 291 combines and varies the laser beams, for example light from red, green and blue lasers may be combined into a single circular beam. A wave-plate 212′, equivalent to the wave-plate sections 212, 214 previously described, may be placed at the opposite edge of the waveguide 291, for instance on a second end of the waveguide 291 opposite the first end, or window 16 or further along the optics. Side view 300 in FIG. 16B shows how a system of two laser package/waveguide combinations, as shown in FIG. 16A, may be combined to generate adjacent beams generated by different laser packages having perpendicular polarizations by implementing two wave-plates 212′ and 214′, equivalent to the setup shown in FIG. 9. In other words, during operation of the system, light beams guided by different waveguides are emitted by the system with different polarizations.

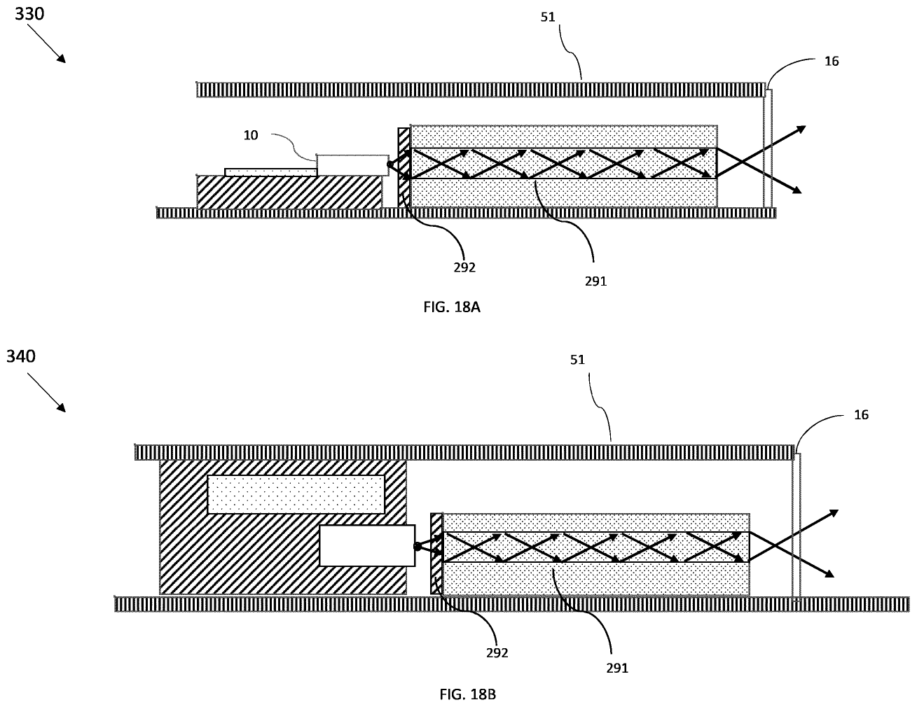

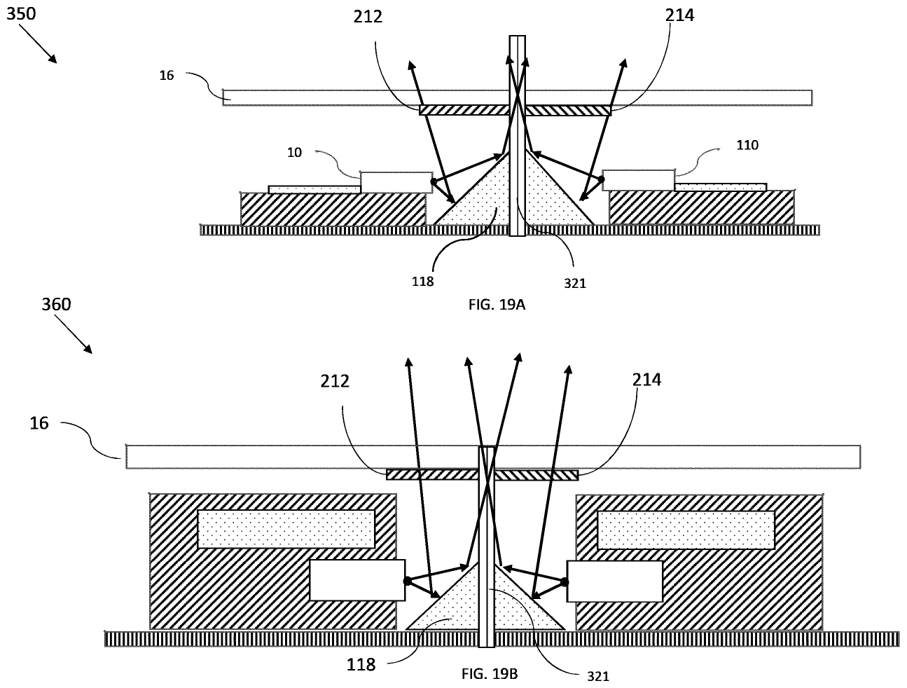

FIGS. 17A and 17B are block diagrams illustrating laterally-oriented laser packages emitting light into a waveguide 291 in accordance with various further embodiments. This type of light injection into the waveguide 291 may be more efficient since the beam fast axis may generate a light distribution that fits the mode shape in the waveguide 291.

The embodiments shown in FIGS. 17A and 17B are similar to the embodiments shown in FIGS. 16A and 16B, except that a laterally-oriented laser package is utilized instead of a flatly-oriented laser package, respectively. For example, side view 310 includes a laterally mounted laser diode injecting light into a waveguide 291 that combines and conditions the laser beam. A wave-plate 212′, equivalent to the wave-plate sections 212, 214 previously described, may be placed at the opposite edge of the waveguide 291 or window 16 or further along the optics. Side view 320 in FIG. 17B shows how two laser package/waveguide combinations, as shown in FIG. 17A, may be combined in a system comprising at least two laser packages to generate adjacent beams having perpendicular polarizations by implementing two wave-plates 212′ and 214′, equivalent to the setup shown in FIG. 9.

FIG. 17C is a block diagram illustrating a system comprising a combination of a flatly-oriented and laterally-oriented laser package emitting light into waveguides in accordance with various further embodiments. Side view 325 shows a system with a flatly-oriented laser package/waveguide combination adjacent to a laterally-oriented laser package/waveguide combination. The perpendicular orientation of the lasers in the laser packages, wherein purely exemplary the flatly-oriented laser package is positioned above and laterally-oriented laser package is positioned below in FIG. 17C, generates perpendicular polarization that is preserved while propagating within the waveguides, resulting in an output polarization of the two sections that is perpendicular. It is also possible to combine perpendicular orientations in free space configurations, for instance similar to the setup shown in FIGS. 13 and 14, as long as the divergence of the two laser sections is equalized, i.e., the fast and slow axis are equalized. This problem does not exist in the embodiment shown in FIG. 17C because the waveguides equalize the output divergence and maintain optimal spacing between adjacent laser output, for example such as RGB.

In order to generate an unpolarized beam from a single laser, the beam must be transmitted through a highly birefringent medium. High birefringence may be generated by using a crystal structure, such as crystal quartz, or by implementing a highly non-circular mode in the waveguide. Light from a laser may be injected into a waveguide having strong modal birefringence, also denoted as polarization mode dispersion. The orientation of the polarization injected from the laser is configured to not overlap with the principle axis of the waveguide, thereby exciting both polarization modes in the waveguide and causing depolarization of the resultant transmitted light. The unpolarized light is then injected into a system similar to the system illustrated in the top view 200 in FIG. 8.

FIGS. 18A and 18B are block diagrams illustrating laser packages emitting light into a waveguide in accordance with various further embodiments. Side view 330 in FIG. 18A shows a flatly-oriented laser package with a laser emitting light into an adjacent wave-plate 292 that is attached to the waveguide 291. The waveguide 291 is preferably birefringent. Opposed to the configuration shown in FIG. 16A, the wave-plate 292 is placed proximate to the laser diode 10 rather than on the opposite side of the waveguide 291. This allows the laser polarization to not overlap with the axis of the waveguide 291. Similarly, side view 340 in FIG. 18B shows a laterally-oriented laser package with a laser emitting light into an adjacent wave-plate 292 that is attached to the waveguide 291. Opposed to the configuration shown in FIG. 17A, the wave-plate 292 is placed at the first end and, thus, proximate to the laser diode rather than on the opposite side of the waveguide 291. Alternatively, in both cases shown in FIGS. 18A and 18B, the laser diode may be placed in any other non-perpendicular orientation and, thus, tilted with respect to the waveguide in order to not have an overlap between the laser beam polarization and the waveguide axis. Preferably, the length of the waveguide is such to depolarize the beam.

Combinations of any of the embodiments described herein may also be possible. For example, laser packages may be arranged to include at least two of the following features: the birefringent waveguide setup shown in FIGS. 18A and 18B, the perpendicular polarization setups shown in FIGS. 16B, 17B, and 17C, and using lasers emitting light of the same color, but wherein one is slightly wavelength-shifted.

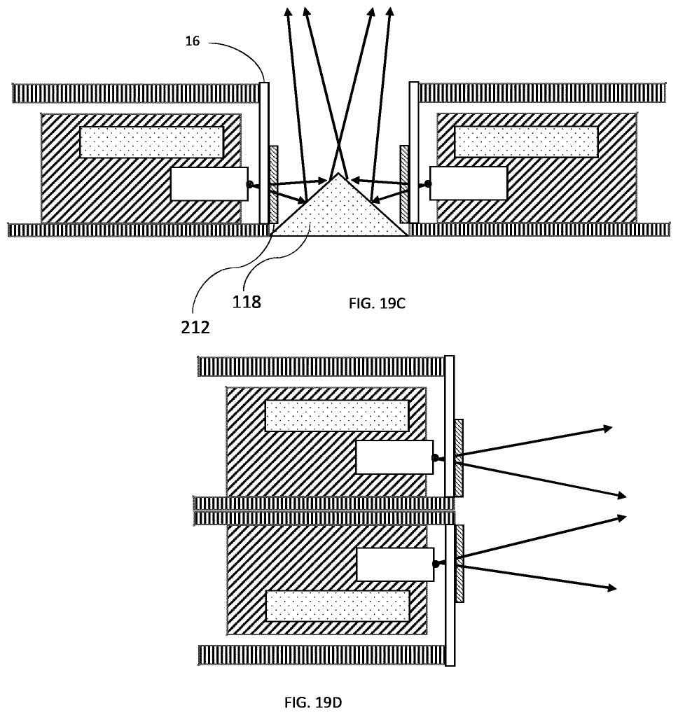

FIGS. 19A to 19D are block diagrams illustrating systems comprising laser packages separated by individual packaging in accordance with various further embodiments. For example, side view 350 in FIG. 19A shows two opposing flatly-oriented laser diodes 10, 110, which can, for instance, each contain a RGB laser pixel, emitting light onto reflecting mirror 118, and up through window 16 through wave-plate sections 212, 214, similar to the embodiment shown in FIG. 9. However, the laser packages may be separated by individual packaging 321. This configuration unifies a single RGB pixel package into a 6-pack laser arrangement. Similarly, side view 360 in FIG. 19B shows two opposing laterally-oriented laser diodes, which can, for instance, each contain a RGB laser pixel, emitting light onto reflecting mirror 118, and up through window 16 through wave-plate sections 212, 214, similar to the embodiment shown in FIG. 10. However, the laser packages may be separated by individual packaging 321. This approach may also be combined with the curved/bowed prisms formed by reflectors 251 and 261 and with the corresponding lenses 252, 253 as illustrated in FIGS. 13 and 14. FIG. 19C shows side emitting sealed packages equivalent to the configuration shown in side view 50 in FIG. 5A placed at opposite sides against reflecting prism 118. FIG. 19D shows the same sealed packages, this time placed back to back to generate parallel light emission.

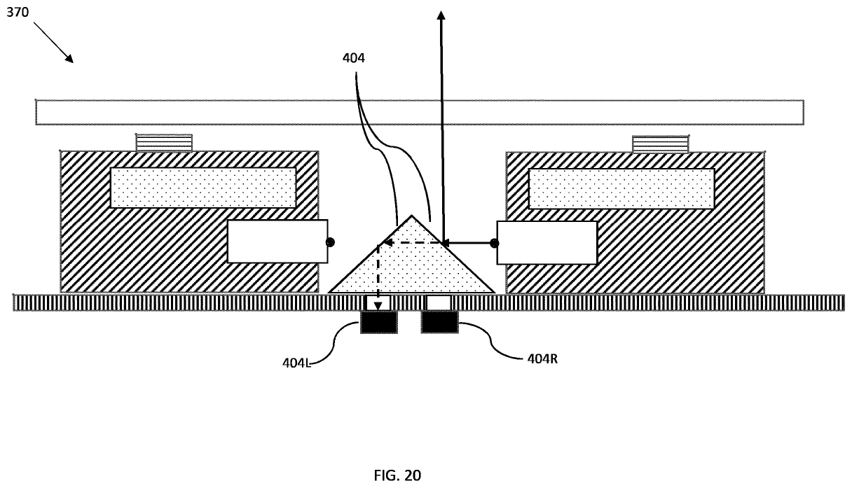

The implementation of lasers in optical systems may necessitate continuous power monitoring of every laser in the system. This may be achieved by placing a fast power detector, e.g., a PIN diode, along the beam path. It can be very beneficial to implement such detector within the laser package to save space. FIG. 20 is a block diagram illustrating a laser package in combination with a photodiode in accordance with various further embodiments. Side view 370 in FIG. 20 shows a compact integration of photo-detectors (PD) 404L, 404R under a prism 404 shared by two lasers. In FIG. 20, only the central beam of the right laser is shown, but the left laser also emits an equivalent light beam. In addition, although FIG. 20 illustrates a laterally-oriented laser package, flatly-oriented laser packages may also be used.

The reflecting surfaces of the prism 404 are partial reflectors, for example having a 95% reflectivity and 5% transmittance. The transmitted light, shown as dashed arrow, impinges on the opposite face of the prism where 95% of it is reflected down toward PD 404L. Similarly, the light from the left laser is reflected towards PD 404R. Because of the optical orientation of the prism 404 and because of the placement of PDs 404L and 404R, minimal scattered light from the right laser will be detected by the left PD 404L and vice versa. This PD placement may be applied to every laser in the package, for example, 6 lasers if red, green, and blue lasers are used on both sides.

Thermal management of lasers in a laser package depends on the heat sensitivity of every laser. Visible wavelength laser diodes that are typically used in AR/VR applications usually have efficiencies, i.e., electrical to optical, on the order of 5 to 10% for green light and exceeding 30% for red and blue light, for example. As a specific example, a laser package may include continuous wave (CW) red (R), green (G), and blue (B) laser diodes operating at around 100 mW. Table 1 shows example laser diode specifications used to simulate the thermal environment of the resulting RGB laser diode package.

TABLE 1
Example laser diode specifications for thermal simulation

| | Wave- | | | | | | | Desired |
|---|---|---|---|---|---|---|---|---|
| Laser | length | | P-opt | I | V | P-elec | Effi- | Tj |
| Color | (nm) | Material | (mW) | (mA) | (V) | (mW) | ciency | (° C.) |
| Blue | 450 | InGaN | 80 | 100 | 5.2 | 520 | 0.15 | <100 |
| Green | 520 | InGaN | 80 | 200 | 6.0 | 1200 | 0.07 | <100 |
| Red | 633 | AlGaInP | 100 | 170 | 2.6 | 440 | 0.23 | <65 |

Table 1 shows that while the green laser dissipates the most heat, the red laser is limited to the lowest temperature. Therefore, in addition to achieving maximal heat conductivity from the lasers to the envelope and from the envelope to the air, there is also a need for differentiation of heat conductivity so that all lasers operate simultaneously at their respective operational temperature without heat from one laser causing overheating of its neighbor laser. Consequently, in order to obtain the required temperatures from all lasers, the heat conductivity of every laser to the envelope should be inversely proportional to the laser temperature difference from nominal environmental temperature and linearly proportional to the heat generated by the laser.

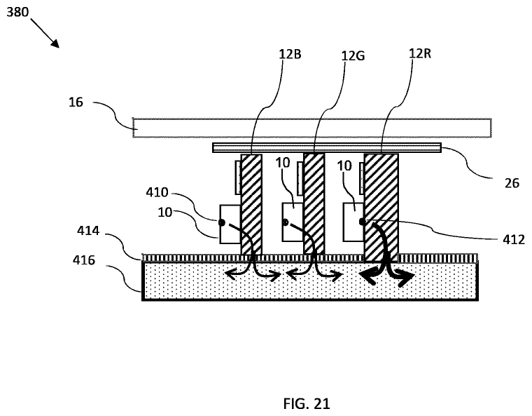

FIG. 21 is a block diagram illustrating a laser package in a side view 380 with heat conductivity modifications in accordance with various further embodiments. The shown laser package is an exemplary RBG laser package with three laser diodes, i.e., diode 10 and sub-mount 12B for blue, diode 10 and sub-mount 12G for green, and diode 10 and sub-mount 12R for red. There is a conducting bridge 26 between the laser diodes 10 and window 16. The laser package includes a few alternatives for modifying heat conductivity, assuming that the red laser diode needs higher thermal conductivity relative to the green and blue laser diodes, assuming a different temperature and a same power dissipation. The following discussion with respect to FIG. 21 is only one example of modifying heat conductivity. Different lasers have different thermal parameters and thus will require different adjustments, but persons of ordinary skill in the art may vary the described approaches, including variations in size and in combinations of the alternatives, to achieve the desired result.

Each of the laser diodes 10 in FIG. 21 dissipates heat to their respective sub-mounts 12B, 12G, and 12R. In order to enable better heat dissipation for the red laser diode 10, sub-mount 12R is wider than sub-mounts 12B and 12G, but the distance between the lasers remains the same. This is achieved by placing the laser needing most heat dissipation as the last, i.e., outermost, laser and having it facing inward as shown for sub-mount 12R.

Heat dissipation through the laser diodes 10 also depends on the location of the emitters. The green and blue laser diodes may have an emitter configuration 410 that is P-side-up while the red laser diode has an emitter configuration 412 that is P-side-down. P-side-up configurations have a lower heat dissipation relative to P-side-down configurations. Using P-side-up for the red laser diode while using P-side-down for the green and blue laser diodes may also enable differentiation in thermal dissipation. The laser diodes may rest on a ‘metal-core-PCB’ that includes a metal core 416 and an insulating cover 414. Sub-mount 12R may be in direct contact with the metal core 416 while the other lasers are in contact with the cover 414, which also achieves differential thermal dissipation.

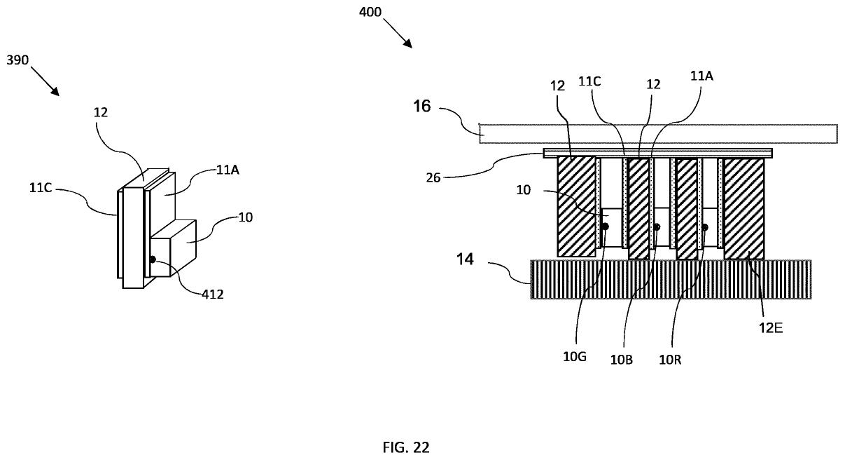

FIG. 22 is a block diagram illustrating a laser in a three-dimensional view 390 and a laser package in a side view 400 with heat conductivity modifications in accordance with various further embodiments. The laser includes laser diode 10 with a P-side-down emitter configuration 412, sub-mount 12, and conductors. In the shown embodiment, the conductors are formed by an anode coating 11A between the laser diode 10 and the sub-mount 12 and a cathode coating 11C on the other side of the sub-mount 12. The laser package according to the side view 400 includes several individual lasers according to the view 390 placed together such that the conductor arranged on the side opposite to the laser diode, i.e., in the shown embodiment the cathode coating 11C of one laser, is in contact with the laser diode of an adjacent laser. Alternatively, the conductors of a laser, i.e., in the shown embodiment the anode and cathode coatings, can also be interchanged.

The laser diodes 10R, 10G, and 10B of the laser package shown in side view 400 dissipate heat in two directions, namely through the sub-mounts 12 on either side of the laser diode. The power connections for each laser diode are made through anode coating 11A on one side and cathode coating 11C on the opposite side. In this configuration, an extra outermost sub-mount 12E improves heat conductivity and the outermost sub-mounts, which are the sub-mount 12 of laser diode 10G and the extra outermost sub-mount 12E in the shown embodiment, may be thicker without increasing laser spacing. In this configuration, the lasers at the sides have the best heat dissipation. For example, the red laser diode 10R may be on one end while the green laser diode 10G may be on the other end, having very high heat generation as shown in Table 1, and the blue laser diode 10B may be in the middle.

As can be seen in FIG. 22, the sub-mounts 12, 12E forming the outermost sub-mounts, with respect to the lateral direction, are preferably free of conductors such as coatings on their respective external side having the surface facing outwards, i.e., away from the laser diodes. Thus, the side of a sub-mount opposite to the laser diode is preferably free of a conductor if that side is an external side of the laser package.

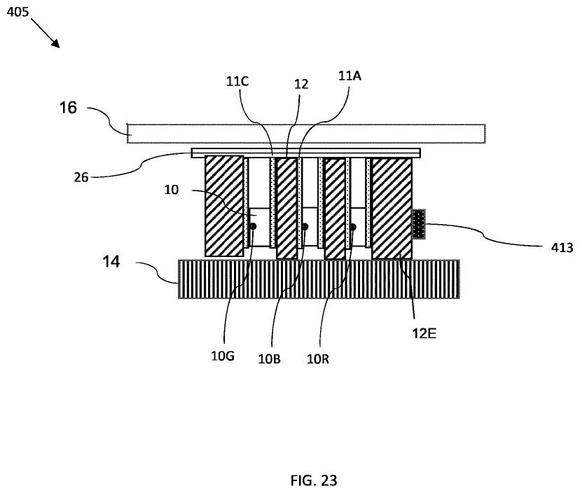

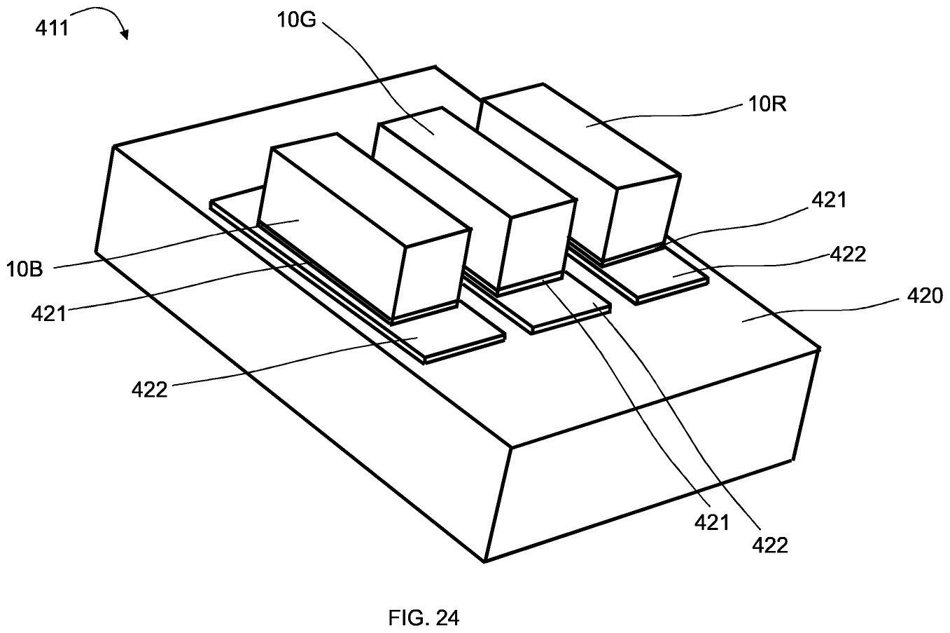

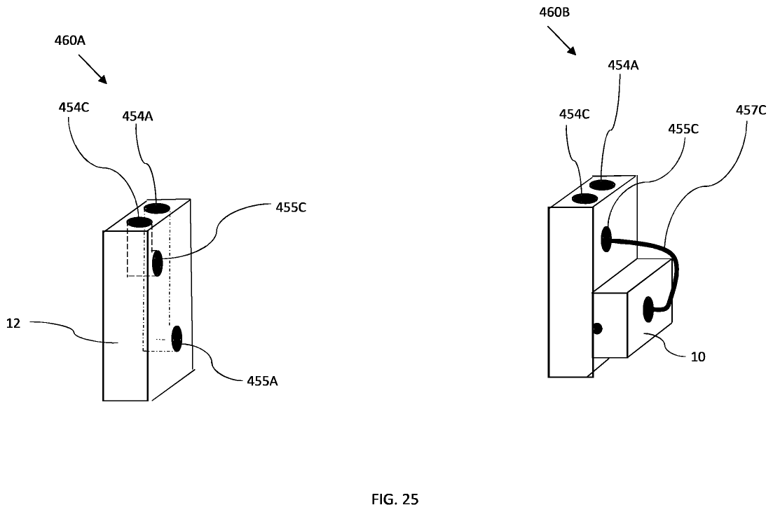

FIG. 23 is a block diagram illustrating a laser package in a side view 405 with heat conductivity modifications and a thermal sensor in accordance with various further embodiments. The laser package is similar to the laser package shown in FIG. 22, with the addition of a temperature sensor 413 like a thermistor or other thermosensor. The temperature sensor 413 may be used to monitor the red diode's 10R temperature during operation. This can be used to provide system feedback to adjust brightness or drive conditions if the diode is becoming warmer than the allowed junction temperature. The temperature sensor 413 may be lithographically placed on the back of the sub-mount 12E or of the sub-mount of laser diode 10R to reduce overall package size.

FIG. 24 is a schematic illustration of a laser for a laser package in a three-dimensional view 411 with conductors formed by metallizations in form of metallized pads 422 on a substrate 420 in accordance with various further embodiments.

The substrate 420 is preferably a sub-mount as described in connection with the other embodiments, or at least a part of a sub-mount. The laser includes RBG laser diodes 10R, 10G, 10B, each diode 10R, 10G, 10B being attached to a respective metallized pad 422 via solder pads 421 or solder joints. The metallized pads 422 are placed on the preferably highly thermally conductive, but electrically insulating substrate 420. The electrical isolation is needed to permit attachment of wire bonds to bond-pads on the substrate 420 (not shown). The substrate 420 may then be bonded onto a laser package or heat transport strap to facilitate heat dissipation. If a common laser package is connected to the substrate 420, it should be composed of a high conductivity material such as AlN, Al, Cu or other materials with thermal conductivities exceeding 100 W/m/K. If the laser is incorporated into AR/VR glasses, the heat removal to air may be further facilitated by a significant heat spreader in the glasses.

If a heat transport strap is connected to the substrate 420, the strap should have a high thermal conductivity in order to carry heat away from the laser diodes for dissipation. The strap may be fabricated with a high thermal conductivity metal such as copper, with appropriate coatings to prevent oxidation over time. The strap may also include small vertical fins to further facilitate heat transport to air via convection. The strap may be painted or coated with a material having emissivity near one in the far IR wavelength range to further facilitate heat removal by radiative emission.

The entire substrate with the laser diodes, and a heat transport strap in some embodiments, should be enclosed in a hermitically-sealed package to prevent exposure to humidity which can degrade the laser dies. Typical materials for solder pads include 80/20 Au—Sn, silver sinter, or other well-known low temperature, high thermal conductivity bonding materials. Organic bonding materials should be avoided to prevent outgassing which again can degrade laser life. The metallized pads on the substrate, to which the laser diodes are bonded via the solder joint or other bonding materials, may be composed of well-known metals. The size of the metallized pads may be changed, e.g., the length or width, to change the rate of heat dissipation. The substrate may be composed of a variety of high thermal conductivity ceramic materials, including alumina or AlN. The substrate should be relatively thin, especially in the case of alumina which has a thermal conductivity κ≈20-30 W/m/K, versus 100-300 W/m/K for AlN. Note that AlN is more compatible with typical CTEs of laser diode materials (3-6×10⁻⁶ K⁻¹) than alumina, but the CTE for alumina is still only about 8×10⁻⁶ K⁻¹, so thermal mismatch may be taken up partially by the less stiff solder layer. This is most important during soldering to minimize the chance of overly straining the laser dies upon solidification of the solder and cooling.

For good heat conductivity, the sub-mount, which can be denoted throughout this description also as carrier or as sub-mount/carrier or as substrate, is preferably composed of a ceramic material, for example, as described before such as aluminum nitride. This material may be printed in various forms and conducting lines may be embedded in it.

FIG. 25 is a block diagram illustrating sub-mounts with embedded conducting lines in accordance with various further embodiments. This may allow direct conductivity from the laser through the conducting bridge 26 or board 14, as depicted in connection with various other embodiments, and out to a power supply. Diagram 460A shows conductors formed by electrical pads 454A, 454C, 455A, 455C. The electrical pad 454C is connected to the electrical pad 455C via an internal conductor, as indicated via dashed lines, while pad 454A is connected by an internal conductor, indicated via dot-dashed lines, to pad 455A. In diagram 460B, the laser diode 10 formed by a laser die is attached to the sub-mount 12 so that one side, e.g., the anode of the die is now directly attached to pad 455A (now obscured) while the upper die side, e.g., the cathode, is wired via conductor 457C to pad 455C. Consequently, pad 454C provides a conduction path to the laser cathode while pad 454A provides a conduction path to the laser anode. Now that the conductivity to the laser is provided from the upper face of the sub-mount/carrier 12, the carrier may be attached to a conducting bridge 26 while direct attachment to a board formed by base 14, preferably using aluminum nitride, enables good heat dissipation. Pads 454C and 454A may be located on the bottom face of sub-mount/carrier 12, thereby enabling electrical conductivity through the board 14.

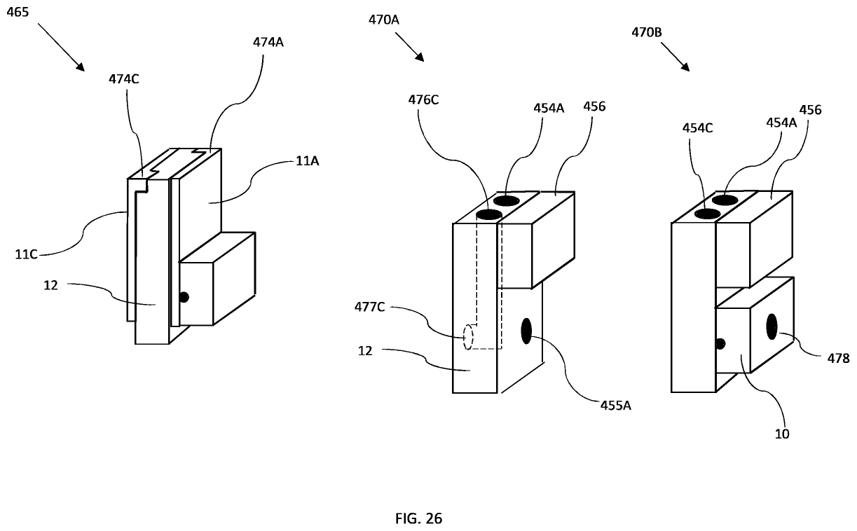

As described above, the laser shown in view 390 in FIG. 22 includes conducting pads 11C and 11A for the cathode and anode respectively. It is possible to connect to these pads through the upper face, via conducting bridge 26, or from the lower face, via base 14. This is shown in FIG. 26, which includes block diagrams illustrating additional sub-mounts with embedded conducting lines in accordance with various further embodiments. In diagram 465, the conducting pads may have extensions to the side pads to facilitate connection of the upper board. For example, cathode pad 11C includes extension 474C and anode pad 11A includes extension 474A.

Diagrams 470A and 470B show how the conductors can be embedded in the sub-mount/carrier 12 for laser packages shown in views 400 and 405 in FIGS. 22 and 23. In diagram 470A, only the sub-mount/carrier 12 is shown. Pad 454A is conductively connected to pad 455A while pad 476C is conductively connected to a pad 477C on the other side, indicated via dashed lines. Extension 456 is added to or a part of sub-mount/carrier 12 in order to fill the gap between the carriers, thereby improving thermal conductivity and mechanical stability. Diagram 470B shows the placement of the laser diode 10 on the carrier from diagram 470A, in which pad 478 will connect to pad 477C of the adjacent carrier. The conductors inside the sub-mount/carrier 12 may be in various shapes, and may be embedded or exposed on the facet of the carrier.

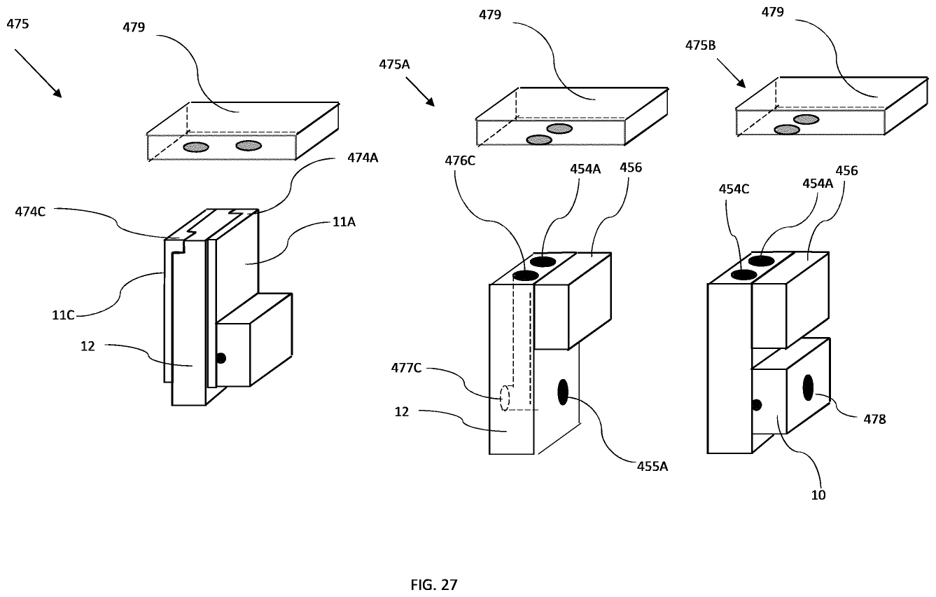

FIG. 27 is a block diagram illustrating PCBs, which can be form or part of a base or a conducting bridge, to be mounted to sub-mounts with embedded conducting lines in accordance with various further embodiments. For the sake of clarity, the PCBs and the sub-mounts are shown separated from each other. As shown in the diagrams 475, 475A, 475B, the PCBs 479 are lined up with the sub-mounts/carriers 12, which are the same sub-mounts as shown in FIG. 26. The PCBs 479 may be made from AlN and mounted with solder bumps as, for example, indium bumps, which connect to the pads of the sub-mount and which are usually used for flip chip attachment, thereby eliminating wire bonds for laser conductions. This aids in high speed pulses for the laser driving schemes.

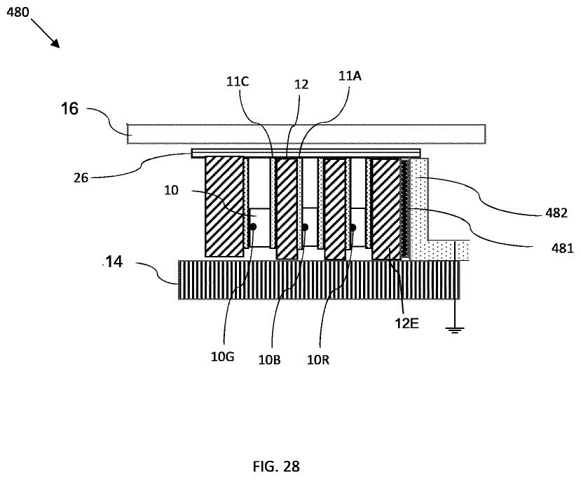

FIG. 28 is a block diagram illustrating a laser package in a side view 480 with a micro-refrigerator in accordance with various further embodiments. The laser package may be similar to the laser package shown in view 400 in FIG. 22. The laser package includes a thermos-electric cooler (TEC) 481, also called a micro-refrigerator. The TEC 481 may be composed of thin film silicon-germanium, which can be as thin as 3 μm with a cooling density of 600/cm², and may be used to cool only or at least the externally placed red laser to accommodate lower required thermal junction temperature. An additional mount 482 is used to then carry away the waste heat.

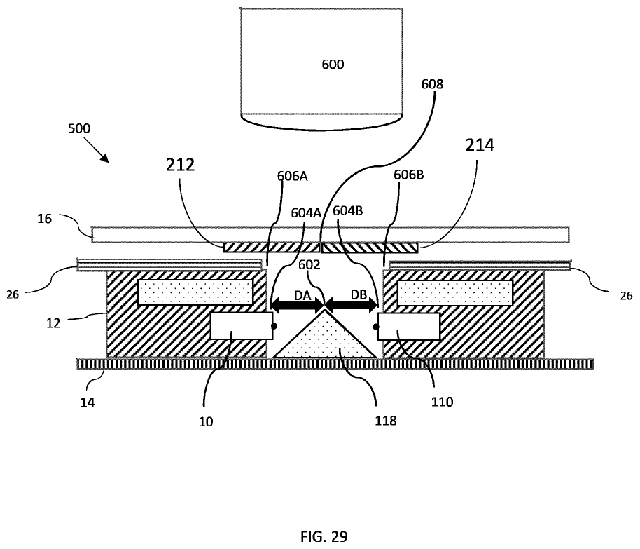

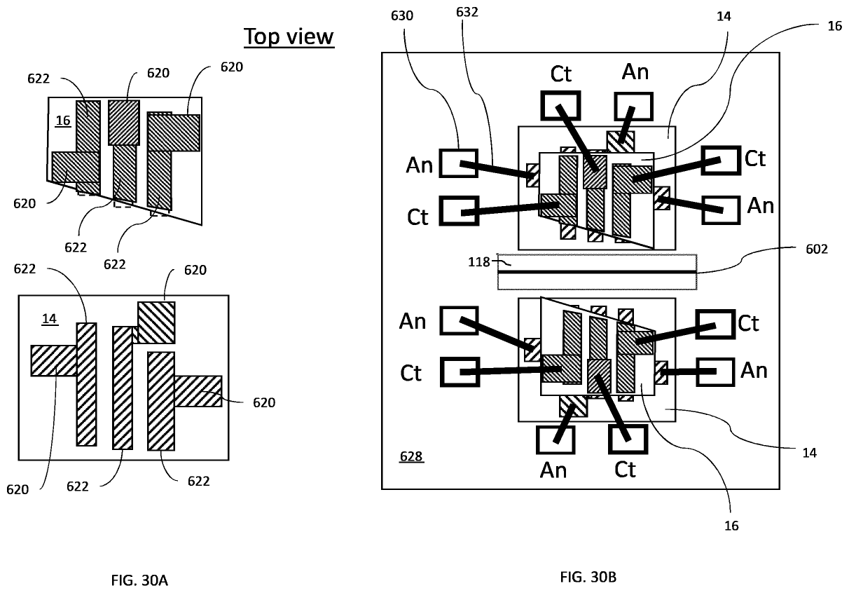

Placement of lasers, e.g., laser diodes 10 and 110 in front of a folding prism, e.g., reflecting mirror 118 as shown in FIG. 6, must be at the same respective distance so that all lasers are collimated simultaneously by the same optics. This can be achieved by visual inspection from the top of the laser package. FIG. 29 is a block diagram illustrating a laterally-oriented laser package in a side view 500 sharing a reflecting mirror 118 and measured by an imaging inspection device 600 in accordance with various further embodiments. The imaging inspection device 600, preferably a microscope, views the system from above. The tip 602 of the prism/reflecting mirror 118 is visible and so are the tips 604A, 604B of the laser diodes 10 and 110, respectively. By setting the respective distance of the two laser diodes 10, 110 to the prisms tip, marked as DA and DB, as observed from imaging inspection device 600 to be equal, the optical path of light from both lasers will be equal. In case that the laser tips 604A, 604B cannot be directly observed, the respective distance between carrier tips 606A and 606B to prism tip 602 may be measured instead, as long as the placement of laser tips 604A, 604B relative to carrier tips 606A, 606B are accurately preset. Conducting bridge 26 must not obscure the space between the carrier tips 606A, 606B or the laser tips 604A, 604B to the imaging inspection device 600. Preferably, all laser tips are visible. When wave-plate sections 212 and 214 are attached to the window 16, then the intermediate line 608 between the wave-plate sections 212, 214 should also be imaged by imaging inspection device 600 and, if necessary, the window 16 should shifted so that the intermediate line 608 is just above prism tip 602. Electrical leads to conducting bridge 26, for example formed by PCBs, or the board formed by base 14 must be taken into account in regard to the accessibility to the external package and the alignment visibility described with respect to FIG. 29. Furthermore, it is preferable that for every laser the anode and the cathode leads are arranged adjacent to each other.

FIGS. 30A and 30B are block diagrams illustrating the layout of upper and lower plates of a laser package in accordance with various further embodiments. The lower plate may be the board formed by the base 14 that conducts to the anode while the upper plate may be the conducting bridge 26 that conducts to the cathode. FIG. 30A shows a top view of the lower plate, for instance formed by base 14, and the upper plate, for instance formed by window 26. The pads 620 are the pads used for wire-bonding or indium bump connectivity. The leads 622 conduct the electrical current to the laser sub-mount/carrier. The elongation shift in position of leads 622 is needed when laser position shift is needed, for example, for chromatic aberration correction. The diagonal edge of the upper plate is needed to enable visibility of all laser tips as described with respect to FIG. 29. The placement of the pads 620 in this embodiment is defined so that they are accessible for wire bonding when integrated with the lasers as shown in the top view in FIG. 30B. FIG. 30B shows the combined block that includes the upper plate, formed by window 26, the lower plate, formed by base 14, and the lasers (in between, not shown). Prism 118, having prism tip 602, is located in between the two blocks. The external package 628 includes pads 630 that lead electricity outside the package (not shown). The pads 620 are connected to package pads 630 by wire leads 632. It is apparent that for each laser, the anode, marked as An, and cathode, marked as Ct, are adjacent such that wires 632 are not crossing and pads are not obscured. This arrangement is important to enable easy wire bonding and fast signal modulation of the lasers without inducing RF leakage.

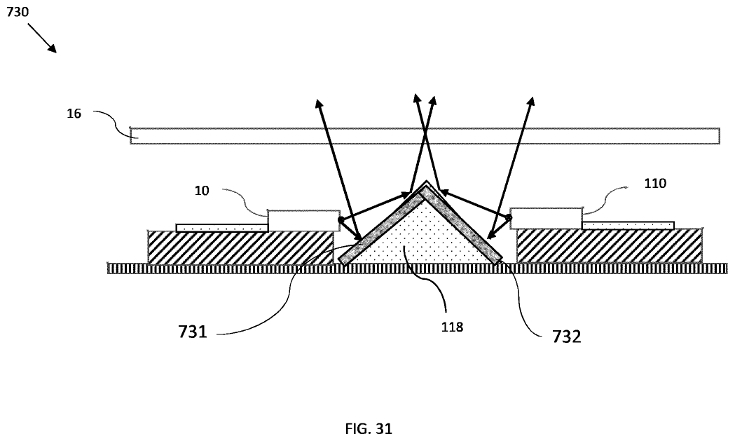

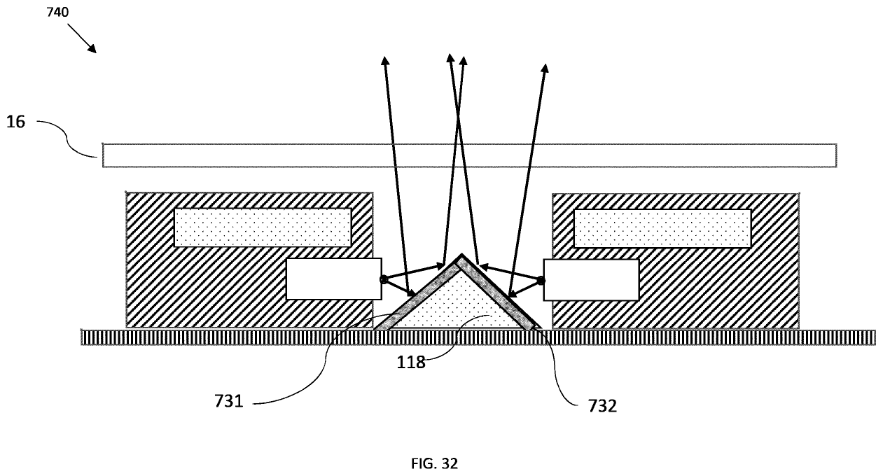

In various further embodiments, additional optical elements may be added to the prism elements of the laser package. These additional optical elements may be used to perform a first level of beam shaping, such as pre-collimation of either the fast axis or slow axis, or both, of the laser light. The additional optical elements may also be used to perform different tasks at different wavelengths. For example, visible lasers require identical focus at the imaging plane while IR lasers do not have this requirement. The optical elements may be used to perform beam divergence correction and focus for RGB lasers to produce higher quality imaging. IR lasers benefit from having beam divergence correction, e.g., with a 1:1 beam ratio, for a variety of reasons, including energy efficiency, possibly very long coherence, and improved collimation for maximal optical efficiency, which is more suited for eye tracking and proximity detection. For example, FIG. 31 is a block diagram in a side view 730 illustrating a flatly-oriented laser package sharing a reflecting mirror with additional optical elements in accordance with various further embodiments, while FIG. 32 is a block diagram in a side view 740 illustrating a laterally-oriented laser package sharing a reflecting mirror with additional optical elements in accordance with various further embodiments. Both FIGS. 31 and 32 show additional optical surface elements 731, 732 on both surfaces of the reflecting prism 118, respectively. The optical surface elements 731, 732 may be either metaoptics or diffractive optics. The optical surface elements 731, 732 reflect light exiting from the laser diodes and may perform beam shaping. The optical surface elements 731, 732 may be aligned by an angle of 45° with respect to the laser light, but may also be aligned by an angle that is greater or smaller than 45°. The optical surface elements 731, 732 may be planarized or non-planarized.

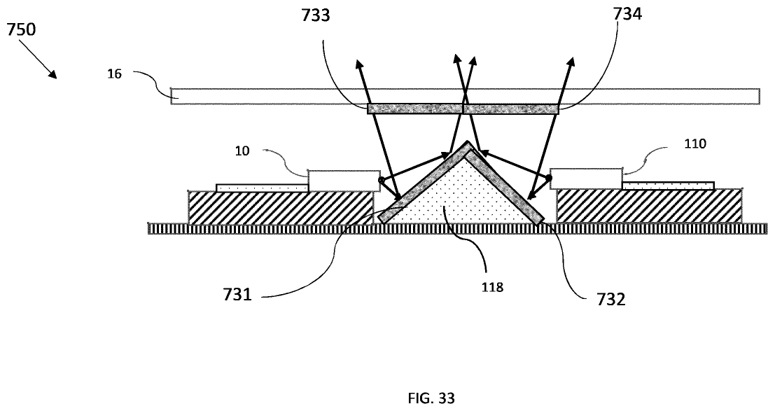

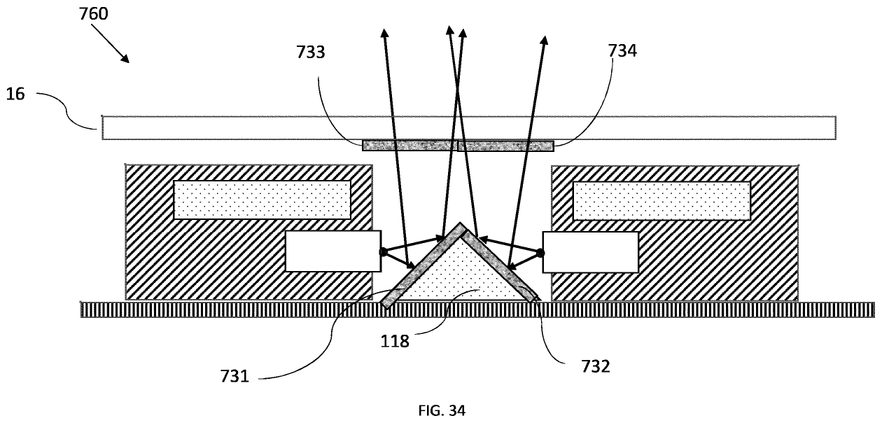

Additional optical elements may also be placed on the underside of the cover glass, formed by window 16, of the laser package. For example, FIG. 33 is a block diagram in a side view 750 illustrating a flatly-oriented laser package sharing a reflecting mirror with additional optical elements in accordance with various further embodiments, while FIG. 34 is a block diagram in a side view 760 illustrating a laterally-oriented laser package sharing a reflecting mirror with additional optical elements in accordance with various further embodiments. Both FIGS. 33 and 34 show additional optical elements 733, 734 underneath window 16. The additional optical elements 733, 734 may be, for example, metaoptics or diffractive optics. The optical elements 731, 732, in conjunction with optical elements 733, 734, enable both intensity and phase correction. The prism 118 and the window 16 upon which the optical elements 731, 732, 733, and 734 may be mounted are not necessarily planar.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

1. A laser package, comprising
a plurality of laser diodes separately attached to at least one sub-mount having respective connecting pads,
wherein, during operation, each of the laser diodes emits light having a fast axis and a slow axis defining a fast axis plane and a slow axis plane,
wherein the fast axis planes of all laser diodes are parallel to each other and the distance between the fast axis planes of at least two laser diodes is smaller than the lateral distance between these laser diodes.

2. The laser package of claim 1, further comprising a prism or reflecting mirror or reflector associated to the at least one sub-mount or to one or more of a plurality of sub-mounts.

3. The laser package of claim 1, further comprising a window.

4. The laser package of claim 1, further comprising at least one of a base and a conducting bridge.

5. The laser package of claim 1, further comprising a metallic or ceramic top cover.

6. The laser package of claim 1, comprising at least two laser assemblies, each laser assembly having at least one laser diode on a sub-mount, wherein the laser assemblies are placed adjacent to each other or opposite to each other with an intermediate prism or reflecting mirror or reflector, so that paralleled light beams are emitted during operation.

7. The laser package of claim 1, further comprising a wave-plate section or wave-plate set to differentiate the output beam polarization originated from different laser diodes.

8. The laser package of claim 1, further comprising at least one photodetector.

9. The laser package of claim 1, further comprising:
a waveguide, wherein light emitted by the laser diodes passes into a first end of the waveguide, and
a wave-plate attached to the first end or a second end of the waveguide.

10. The laser package of claim 1, wherein:
each of a plurality of sub-mounts are placed adjacent to each other; and
the sub-mount generating the most heat is located at one end of the laser package and is oriented such that the one or more laser diodes on the sub-mount face inward.

11. The laser package of claim 1, wherein at least one of a plurality of sub-mounts has a p-side-up laser diode configuration and at least one of the plurality of sub-mounts has a p-side-down laser diode configuration.

12. The laser package of claim 1, wherein:
the laser package comprises a base and plurality of sub-mounts with at least one laser diode,
the base comprises a metal core printed circuit board comprising a metal core and an insulating cover; and
each of the sub-mounts with at least one laser diode is connected to the insulating cover except for the sub-mount with at least one laser diode generating the most heat, which is connected to the metal core printed circuit board.

13. The laser package of claim 1, comprising a plurality of sub-mounts with at least one laser diode,
wherein each of the sub-mounts further comprises:
a conductor between the sub-mount and the at least one laser diode; and
a further conductor on the other side of the sub-mount in case that other side is not an external side.

14. The laser package of claim 1, further comprising a temperature sensor on a sub-mount.

15. The laser package of claim 1, further comprising at least one conductor formed by a metallized pad between each sub-mount and a base or conducting bridge.

16. The laser package of claim 1, further comprising a reflecting optic configured to perform beam conditioning, wherein beam conditioning may include anisotropy correction, collimation, and coherence control due to a surface structure or a coating, and wherein the surface structure or coating comprises at least one of a metasurface and a concave or convex shape of the reflecting optic.

17. A system, comprising at least two laser packages, each laser package comprising
at least one laser diode on a sub-mount,
a waveguide, wherein light emitted by the at least one laser diode passes into a first end of the waveguide, and
a wave-plate arranged at a second end of the waveguide opposite the first end,
so that, during operation, light beams guided in different waveguides are emitted by the system with different polarizations.

18. The system according to claim 17, wherein the polarizations of the laser packages are orthogonal to each other.

19. A system, comprising at least two laser packages, each laser package comprising
at least one laser diode on a sub-mount,
a birefringent waveguide, wherein a beam of light emitted by the at least one laser diode passes into a first end of the waveguide,
wherein, for each laser package,
a wave-plate is placed at the first end of the waveguide or wherein the at least one laser diode is tilted relative to waveguide, so that a beam polarization entering the waveguide has no overlap with the waveguide axis, and
a length of the waveguide is such to depolarize the beam.

20. The system of claim 17, wherein the two laser packages are oriented orthogonal to each other.
